(19) United States
(12) Patent Application Publication
(10) Pub. No.: US 2025/0297158 A1
(43) Pub. Date: Sep. 25, 2025

(54) QUANTUM DOT COMPOSITION, METHOD FOR MANUFACTURING QUANTUM DOT COMPOSITION, AND DISPLAY DEVICE

(71) Applicant: Samsung Display Co., Ltd., Yongin-si (KR)

(72) Inventors: KAWON PAK, Yongin-si (KR); DOOHYUN LEE, Yongin-si (KR)

(73) Assignee: Samsung Display Co., Ltd., Yongin-si (KR)

(21) Appl. No.: 19/058,355

(22) Filed: Feb. 20, 2025

(30) Foreign Application Priority Data
Mar. 22, 2024 (KR) 10-2024-0040008

(51) Int. Cl. C09K 11/62; B82Y 20/00; B82Y 40/00; C09K 11/02; H10H 29/80; H10H 29/851; H10K 59/38; H10K 59/80; H10K 102/00

(52) U.S. Cl. CPC C09K 11/621; B82Y 20/00; B82Y 40/00; C09K 11/025; H10H 29/8513; H10H 29/882; H10K 59/38; H10K 59/877; H10K 2102/331

(57) ABSTRACT

Embodiments provide a quantum dot composition, a display device produced from the quantum dot composition, and a method for manufacturing the quantum dot composition. The quantum dot composition includes a scatterer, a first quantum dot including a first core, a second quantum dot including a second core that is different from the first core, a first ligand bonded to a surface of the first quantum dot, a second ligand bonded to the surface of a second quantum dot, and a scatterer ligand bonded to a surface of the scatterer, wherein each of the first ligand and the second ligand each makes a chemical bond to the scatterer ligand.

### CROSS-REFERENCE TO RELATED APPLICATION(S)

This patent application claims priority to and benefits of Korean Patent Application No. 10-2024-0040008 under 35 U.S.C. § 119, filed on Mar. 22, 2024, in the Korean Intellectual Property Office, the entire contents of which are incorporated herein by reference.

### BACKGROUND

### 1. Technical Field

The disclosure relates to a quantum dot composition, a method for manufacturing the quantum dot composition and a display device.

### 2. Description of the Related Art

Various display devices have been developed for use in multimedia devices such as a television, a mobile phone, a tablet computer, a navigation device, and a game console. The display device includes a display module that includes a so-called self-luminous light emitting element that achieves display by emitting light from a light emitting material.

In order to improve the color reproducibility of a display device, different types of light control layers may be included, depending on the pixels. The light control layer may transmit only light of a light source in a partial wavelength range or may convert the wavelength range of a source light. Development of light emitting elements using quantum dots as a light emitting material has been conducted, and there is a demand to improve the luminous efficiency and high color characteristics of light emitting elements using quantum dots.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a quantum dot composition that may exhibit improved luminous efficiency properties.

The disclosure further provides a method for manufacturing a quantum dot composition, with improved process reliability.

The disclosure further provides a display device having improved luminous efficiency by including a quantum dot complex.

According to an embodiment, a quantum dot composition may include: a scatterer; a first quantum dot including a first core; a second quantum dot including a second core that is different from the first core; a first ligand bonded to a surface of the first quantum dot; a second ligand bonded to a surface of the second quantum dot; and a scatterer ligand bonded to a surface of the scatterer, wherein the first ligand and the second ligand may each make a chemical bond to the scatterer ligand.

In an embodiment, the first quantum dot and the second quantum dot may each absorb first light to emit second light that has a wavelength that is longer than a wavelength of the first light.

In an embodiment, a maximum emission wavelength range of the first quantum dot and a maximum emission wavelength range of the second quantum dot may each independently be in a range of about 510 nm to about 550 nm.

In an embodiment, the first core may include a first semiconductor nanocrystal; the second core may include a second semiconductor nanocrystal; and the first semiconductor nanocrystal and the second semiconductor nanocrystal may each independently be a Group II-VI compound, a Group III-VI compound, a Group I-II-VI compound, a Group III-V compound, a Group III-II-V compound, a Group IV-VI compound, a Group IV element, a Group IV compound, or any combination thereof.

In an embodiment, the first core may include InP, and the second core may include AgInGaS.

In an embodiment, the first ligand may include a first head part that is bonded to the surface of the first quantum dot. and a first tail part that is separated from the surface of the first quantum dot and makes a chemical bond to the scatterer ligand; and the second ligand may include a second head part that is bonded to the surface of the second quantum dot, and a second tail part that is separated from the surface of the second quantum dot and makes a chemical bond to the scatterer ligand.

In an embodiment, the first ligand may further include a first connection part connecting the first head part and the first tail part; and the second ligand may further include a second connection part connecting the second head part and the second tail part.

In an embodiment, a sum of the amount of the first quantum dot and the amount of the second quantum dot may be in a range of about 30 wt % to about 38 wt %, based on a total weight of the quantum dot composition.

In an embodiment, an amount of the scatterer may be in a range of about 2 wt % to about 8 wt %, based on a total weight of the quantum dot composition.

In an embodiment, the scatterer may include a first scatterer in which a first scatterer ligand that makes a chemical bond to the first ligand is bonded to a surface of the first scatterer, and a second scatterer in which a second scatterer ligand that makes a chemical bond to the second ligand is bonded to a surface of the second scatterer.

In an embodiment, a sum of the amounts of the first quantum dots, the first ligand, the first scatterer and the first scatterer ligand may be defined as a first weight; a sum of the amounts of the second quantum dots, the second ligand, the second scatterer and the second scatterer ligand is defined as a second weight; and a ratio of the first weight to the second weight may be in a range of about 1:1 to about 2:1.

In an embodiment, the first quantum dot may further include a first shell surrounding the first core; the second quantum dot may further include a second shell surrounding the second core; the first ligand may be bonded to a surface of the first shell; and the second ligand may be bonded to a surface of the second shell.

According to an embodiment, a display device may include: a display panel; and a light conversion layer disposed on the display panel and including light control parts, wherein
at least one of the light control parts may include a quantum dot complex; the quantum dot complex may include a scatterer, a first quantum dot including a first core, a second quantum dot including a second core that is different from the first core, a first ligand bonded to a surface of the first quantum dot, a second ligand bonded to a surface of the second quantum dot, and a scatterer ligand bonded to a surface of the scatterer; and the first ligand and the second ligand may each make a chemical bond to the scatterer ligand.

In an embodiment, the display panel may include a light emitting element producing first light; and the light conversion layer may include a first light control part that transmits the first light, a second light control part that converts the first light into second light, and a third light control part that converts the first light into third light.

In an embodiment, a blue light absorption rate of the light control part including the quantum dot complex among the light control parts may be greater than or equal to about 90%.

In an embodiment, when excited light having a wavelength of about 450 nm is irradiated to the light control part including the quantum dot complex among the light control parts, an external quantum efficiency (EQE) may be greater than or equal to about 35%.

According to an embodiment, a method for manufacturing a quantum dot composition may include: providing a first quantum dot with a first ligand bonded to a surface of the first quantum dot, the first quantum dot including a first core; providing a second quantum dot with a second ligand bonded to a surface of the second quantum dot, the second quantum dot including a second core that is different from the first core; providing a scatterer with a scatterer ligand bonded to a surface of the scatterer; mixing the first quantum dot with the first ligand bonded thereto, the second quantum dot with the second ligand bonded thereto, and the scatterer with the scatterer ligand bonded thereto to provide a preliminary quantum dot composition; and providing the preliminary quantum dot composition with heat or light to make a chemical bond between the first ligand and the scatterer ligand and between the second ligand and the scatterer ligand.

In an embodiment, the scatterer ligand may include a first functional group that makes a chemical bond to each of the first ligand and the second ligand, and the first functional group may include at least one of a thiol group, an amine group, a hydroxyl group, an azide group, and an oxetanyl group.

In an embodiment, the first ligand may include a second functional group that makes a chemical bond to the first functional group, the second ligand may include a third functional group that makes a chemical bond to the first functional group, and the second functional group and the third functional group may each independently include at least one of an alkenyl group, an alkynyl group, a carboxyl group, an acyl halide, and a (meth)acrylate group.

In an embodiment, the providing of the preliminary quantum dot composition may include mixing the first quantum dot with the first ligand bonded thereto and the scatterer with the scatterer ligand bonded thereto to provide a first preliminary quantum dot composition, and mixing the second quantum dot with the second ligand bonded thereto and the scatterer with the scatterer ligand bonded thereto to provide a second preliminary quantum dot composition; and the providing the preliminary quantum dot composition with heat or light to make a chemical bond between the first ligand and the scatterer ligand and between tithe second ligand and the scatterer ligand may include providing each of the first preliminary quantum dot composition and the second preliminary quantum dot composition with heat or light, and mixing the first preliminary quantum dot composition that has been provided with the heat or light and the second preliminary quantum dot composition that has been provided with the heat or light.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will be more apparent by describing in detail embodiments thereof with reference to accompanying drawings, in which:

FIG. 1 is a schematic perspective view of an electronic device according to an embodiment;

FIG. 2 is an exploded schematic perspective view of an electronic device according to an embodiment;

FIG. 3 is a schematic cross-sectional view of a display device according to an embodiment, corresponding to line I-I′ in FIG. 1;

FIG. 4 is an enlarged schematic plan view of a portion of a display device according to an embodiment;

FIG. 5 is a schematic cross-sectional view of a display device according to an embodiment;

FIGS. 6A and 6B are each a schematic diagram of the structures of quantum dots according to embodiments;

FIG. 7 is a graph showing absorption and emission spectrums of a light conversion pattern including a single type of quantum dots and a light conversion pattern including two types of quantum dots;

FIG. 8 is a schematic cross-sectional view of a display device according to an embodiment;

FIG. 9A is a schematic cross-sectional view of a display device according to an embodiment;

FIG. 9B is a schematic cross-sectional view of a light emitting element according to an embodiment;

FIG. 10 is a flowchart of a method for manufacturing a quantum dot composition according to an embodiment;

FIG. 11, FIG. 12A and FIG. 12B are each a diagram of steps in the method for manufacturing a quantum dot composition according to an embodiment;

FIG. 13 is a flowchart of a method for manufacturing a quantum dot composition according to an embodiment;

FIG. 14A and FIG. 14B are each a schematic diagrams showing steps in the method for manufacturing a quantum dot composition according to an embodiment;

FIG. 15A is a flowchart of a method for manufacturing a display device according to an embodiment;

FIG. 15B is a flowchart of steps of forming a light control layer according to an embodiment; and

FIG. 16A, FIG. 16B, and FIG. 16C are each a schematic cross-sectional view of steps in the method for manufacturing a quantum dot composition according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (for example, the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, am 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like, but embodiments are not limited thereto.

In the specification, an alkenyl group may be a hydrocarbon group that includes one or more carbon-carbon double bonds in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styrylvinyl group, etc., but embodiments are not limited thereto.

In the specification, an alkynyl group may be a hydrocarbon group that includes one or more carbon-carbon triple bonds in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, an aryl group may be any functional group or substituent derived from an aromatic hydrocarbon ring. An aryl group may be monocyclic or polycyclic. The number ring-forming carbon atoms in an aryl group may be 6 to 60, 6 to 50, 6 to 40, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and the like, but embodiments are not limited thereto.

In the specification, a heteroaryl group may include at least one of B, O, N, P, Si, and S as a heteroatom. If a heteroaryl group includes two or more heteroatoms, two or more heteroatoms may be the same or different from each other. A heteroaryl group may be monocyclic or polycyclic. The number of ring-forming carbon atoms in a heteroaryl group may be 2 to 60, 2 to 50, 2 to 40, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isooxazole group, an oxazole group, an oxadiazole group, a thiadiazole group, a phenothiazine group, a dibenzosilole group, a dibenzofuran group, and the like, but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, an acyl halide may be a substituent having a structure according to Structure S1:

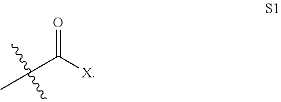

In Structure S1, X may be a halogen atom.

In the specification, a hydroxyl group may be a substituent having a “—OH” structure.

In the specification, a thiol group may be a substituent having a “—SH” structure.

In the specification, a thio group may be an alkyl thio group or an aryl thio group. A thio group may be a sulfur atom that is bonded to an alkyl group or to aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and the like, but embodiments are not limited thereto.

In the specification, an oxy group may be an oxygen atom that is bonded to an alkyl group or an aryl group as described above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, and the like. However, embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group and the like, but embodiments are not limited thereto.

In the specification, a dithioic acid group may be a substituent that has a structure of —C(═S)SR. R may be a hydrogen atom, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms.

In the specification, a phosphine group may be an alkyl phosphine group or an aryl phosphine group. A phosphine group may be a phosphorus atom that is bonded to an alkyl group or to an aryl group as defined above. Examples of a phosphine group may include a methylphosphine group, an ethylphosphine group, a propylphosphine group, a butylphosphine group, a pentylphosphine group, a hexylphosphine group, an octylphosphine group, a cyclopentylphosphine group, a cyclohexylphosphine group, a phenylphosphine group, a diphenylphosphine group, a triphenylphosphine group and the like, but embodiments are not limited thereto.

In the specification, a carboxyl group may be a substituent represented by Structure C1:

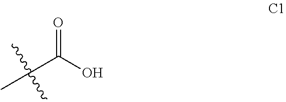 [SMILES: *C(=O)O]

In the specification, the term (meth)acrylate may refer to an acrylate group or a methacrylate group.

In the specification, the symbols

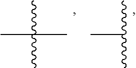

and [symbol] each represents a bond to a neighboring atom in a corresponding formula or moiety.

Hereinafter, a quantum dot composition, a method for manufacturing the quantum dot composition and a display device according to an embodiment will be explained with reference to the drawings.

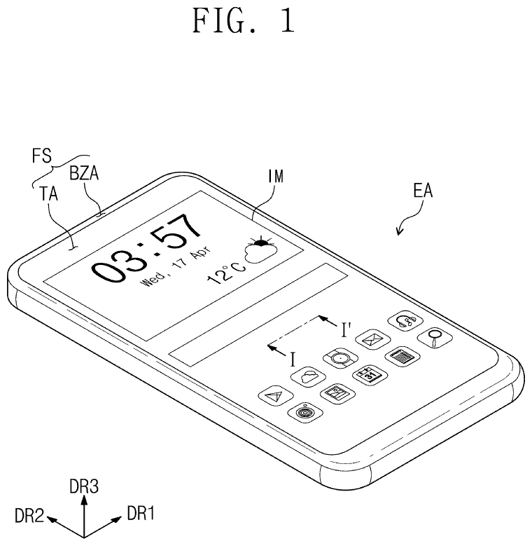

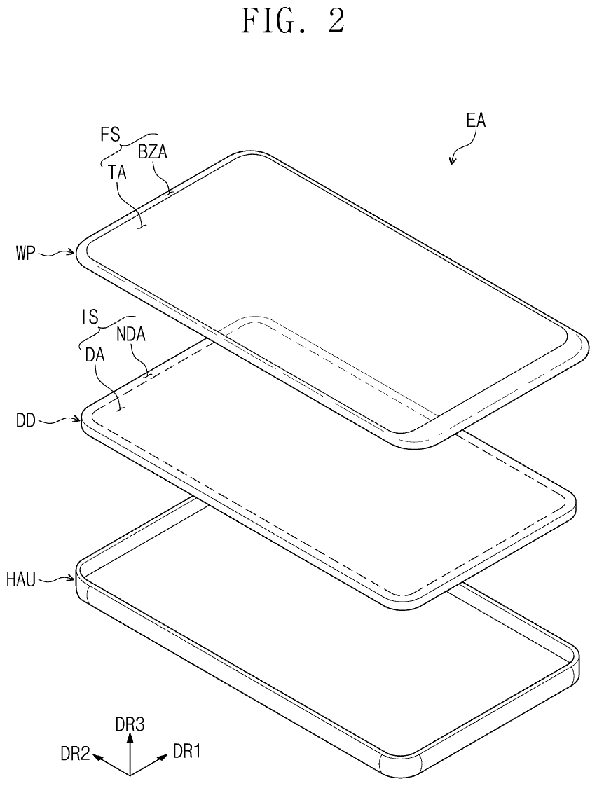

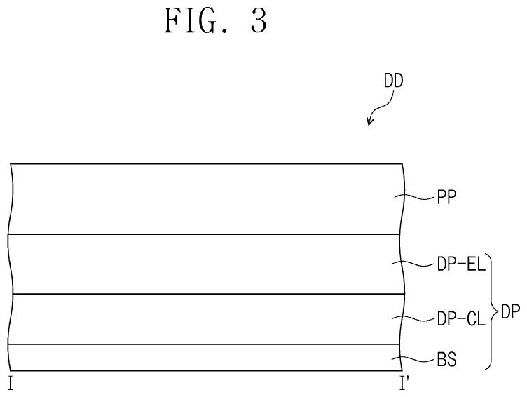

FIG. 1 is a schematic perspective view of an electronic device EA according to an embodiment. FIG. 2 is an exploded schematic perspective view of an electronic device EA according to an embodiment. FIG. 3 is a schematic cross-sectional view of a display device DD according to an embodiment, which corresponds to virtual line I-I′ in FIG. 1.

In an embodiment, an electronic device EA may be a large-sized electronic device such as a television, a monitor, or a billboard. In another embodiment, the electronic device EA may be a small-sized or a medium-sized electronic device such as a personal computer, a laptop computer, a personal digital device, a car navigation unit, a game console, a smartphone, a tablet, or a camera. These are presented only as examples and other electronic devices may be employed. As an example, the electronic device EA shown in FIGS. 1 and 2 is a smartphone, for convenience of explanation.

The electronic device EA may include a display device DD and a housing HAU. The display device DD may display image IM through a display surface IS, and a user may view the image provided through a transparent area TA corresponding to the front surface FS of the electronic device EA. The image IM may include a static image as well as a dynamic image. In FIG. 1, the front surface FS is shown as being parallel to a plane defined by a first direction DR1 and a second direction DR2 that crosses the first direction DR1. However, this is only an illustration, and in another embodiment, the front surface FS of the electronic device EA may have a curved shape.

A normal direction of the front surface FS of the electronic device EA, for example, a direction in which the image IM is displayed among the thickness directions of the electronic device EA, is indicated by a third direction DR3. A front surface (or top) and a rear surface (or bottom) of each member may be distinguished by the third direction DR3. The directions indicated by the first to third directions DR1, DR2, and DR3 are relative concepts and may be converted to other directions.

Although not shown in the drawings, the electronic device EA may include a foldable display device including a folding area and a non-folding area, or a bending display device including at least one bending part.

The front surface FS of the electronic device EA may correspond to the front surface of the display device DD and may correspond to the front surface of a window WP. Accordingly, the front surface of the electronic device EA, the front surface of the display device DD, and the front surface of the window WP use the same reference symbol FS.

The housing HAU may accommodate the display device DD. The housing HAU may cover the display device DD so as to expose the top of the display surface IS of the display device DD. The housing HAU may cover the side surface and the bottom of the display device DD and may expose the entire top. However, embodiments are not limited thereto, and the housing HAU may cover a portion of the top as well as the side surface and the bottom of the display device DD.

In the electronic device EA according to an embodiment, a window WP may include an optically transparent insulating material. The window WP may include a transparent area TA and a bezel area BZA. The front surface FS of the window WP including the transparent area TA and the bezel area BZA corresponds to the front surface FS of the electronic device EA.

In FIG. 1 and FIG. 2, the transparent area TA is shown as a rectangular shape with rounded corners. However, this is only an example, and the transparent area TA may have various shapes and is not limited to a single embodiment.

The transparent area TA may be an optically transparent area. The bezel area BZA may be an area having a relatively low light transmittance compared to the transparent area TA. The bezel area BZA may have a color (e.g., a desired or a selectable color). The bezel area BZA may be adjacent to the transparent area TA and may surround the transparent area TA. The bezel area BZA may define the shape of the transparent area TA. However, embodiments are not limited to what is illustrated, and the bezel area BZA may be disposed adjacent to only one side of the transparent area TA, or some portions thereof may be omitted.

The display device DD may be disposed below the window WP. In the specification, the term “below” may refer to a direction that is opposite to the direction in which the display device DD provides images.

In an embodiment, the display device DD may be configured to produce an image IM. The image IM produced from the display device DD may be displayed on a display surface IS and may be viewed by a user through the transparent area TA from the outside. The display device DD may include a display area DA and a non-display area NDA. The display area DA may be an area that is activated according to electrical signals. The non-display area NDA may be an area covered by the bezel area BZA. The non-display area NDA may be adjacent to the display area NDA. The non-display area NDA may surround the display area DA.

Referring to FIG. 3, the display device DD may include a display panel DP and a light control layer PP disposed on the display panel DP. The display panel DP may include a display element layer DP-EL. The display element layer DP-EL may include a light emitting element ED.

The light control layer PP may be disposed on the display panel DP to control light that is reflected at the display panel DP from an external light. For example, the light control layer PP may include a polarization layer or a color filter layer.

In an embodiment, in the display device DD, the display panel DP may be an emission type display panel. For example, the display panel DP may be a quantum dot light emitting display panel that includes a quantum dot light emitting element. However, embodiments are not limited thereto.

The display panel DP may include a base substrate BS, a circuit layer DP-CL disposed on the base substrate BS, and a display element layer DP-EL disposed on the circuit layer DP-CL.

The base substrate BS may provide a base surface on which the display element layer DP-EL is disposed. The base substrate BS may be a glass substrate, a metal substrate, a plastic substrate, or the like. However, embodiments are not limited thereto, and the base substrate BS may include an inorganic layer, an organic layer, or a composite material layer. The base substrate BS may be a flexible substrate which may be readily bent or folded.

In an embodiment, the circuit layer DP-CL may be disposed on the base substrate BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting element ED of the display element layer DP-EL.

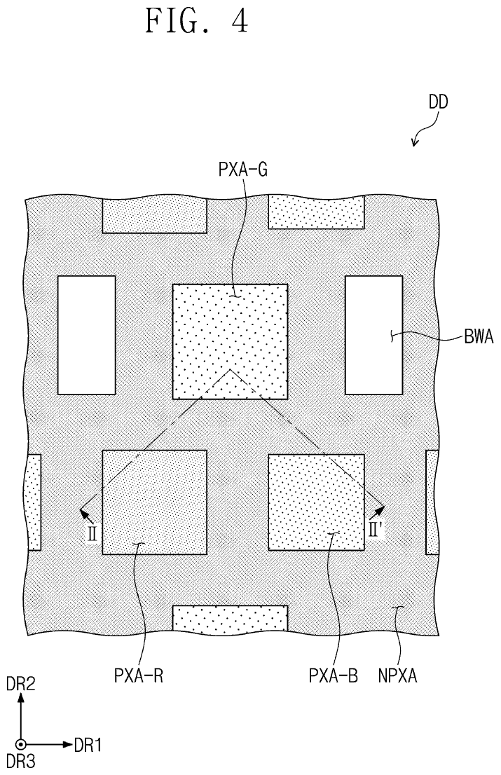

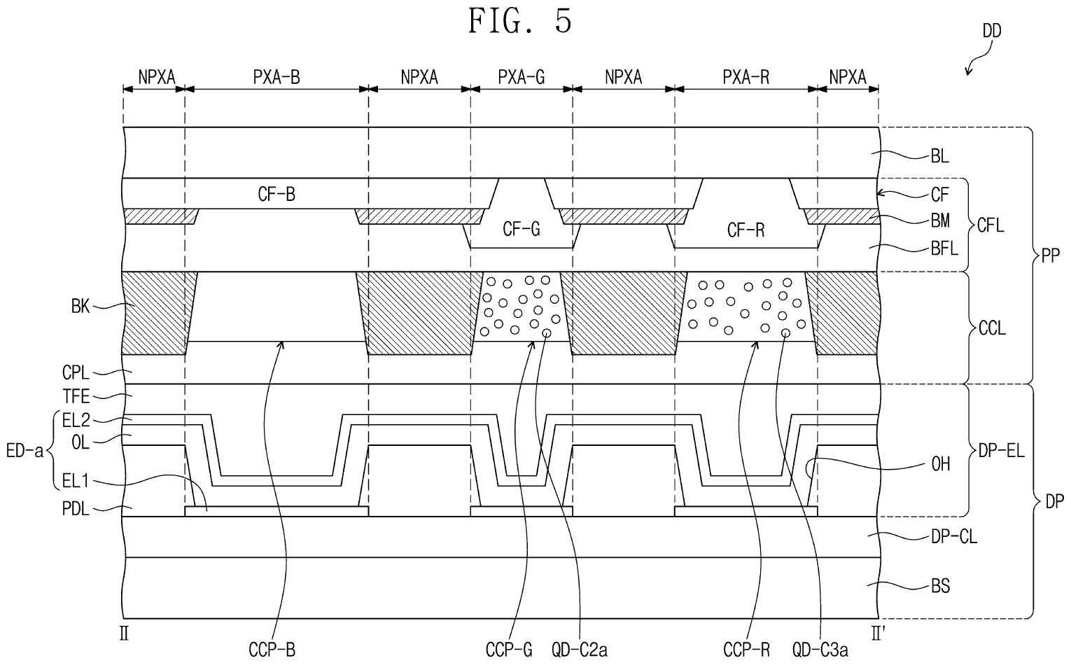

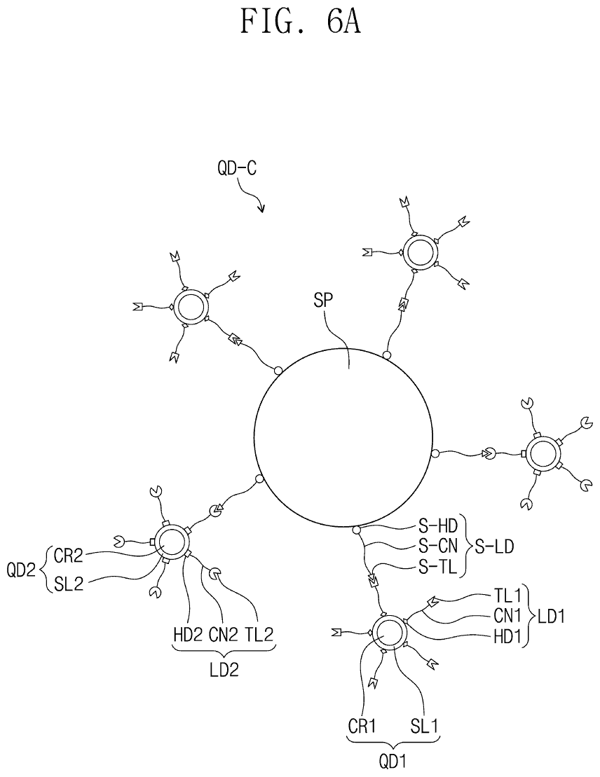

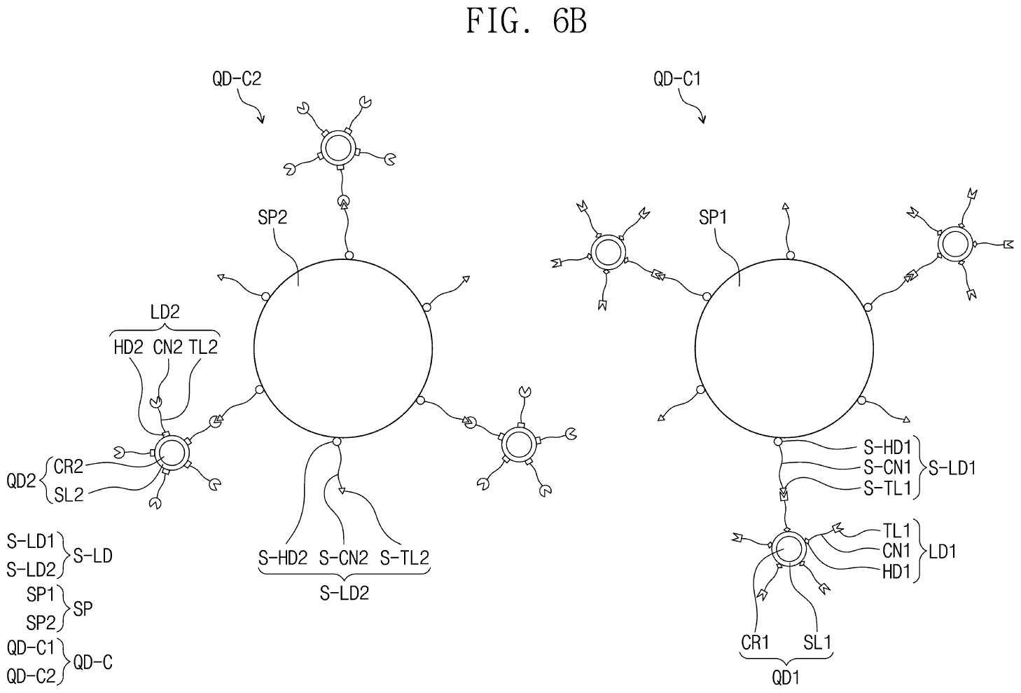

FIG. 4 is an enlarged schematic plan view of a portion of a display device DD according to an embodiment. FIG. 5 is a schematic cross-sectional view of a display device DD according to an embodiment. FIG. 5 shows a portion that corresponds to virtual line II-II′ in FIG. 4. FIG. 6A and FIG. 6B are each a schematic diagram that shows a structure of a quantum dot complex according to an embodiment.

Referring to FIG. 4 and FIG. 5, the display device DD may include a peripheral area NPXA and light emitting areas PXA-B, PXA-G, and PXA-R. The light emitting areas PXA-B, PXA-G, and PXA-R may each be an area emitting light produced from the light emitting element ED-a. The light emitting areas PXA-B, PXA-G, and PXA-R may be separated from each other in a plan view.

The light emitting areas PXA-B, PXA-G, and PXA-R may be divided into groups according to a color of emitted light. In the display device DD shown in FIG. 4 and FIG. 5, three light emitting areas PXA-B, PXA-G, and PXA-R respectively emitting blue light, green light, and red light are shown as an example. For example, the display device DD according to an embodiment may include a first light emitting area PXA-B, a second light emitting area PXA-G, and a third light emitting area PXA-R, which are separated from each other. In the specification, the first light emitting area PXA-B may be a blue light emitting area, the second light emitting area PXA-G may be a green light emitting area, and the third light emitting area PXA-R may be a red light emitting area.

In FIG. 4, the first to third light emitting areas PXA-B, PXA-G, and PXA-R are shown to have a same shape and areas of different sizes in a plan view, but embodiments are not limited thereto. The areas of at least two of the first to third light emitting areas PXA-B, PXA-G, and PXA-R may be the same as each other, in terms of size or shape. The areas of the first to third light emitting areas PXA-B, PXA-G, and PXA-R may be set on the basis of a color of emitted light. Among the primary colors, an area of a light emitting area that emits green light may be the largest in size, and the area of a light emitting area that emits blue light may be the smallest in size.

The light emitting areas PXA-B, PXA-G, and PXA-R may be distinguished from each other by a pixel definition layer PDL. The peripheral area NPXA may include areas between the light emitting areas PXA-B, PXA-G, and PXA-R and may correspond to the pixel definition layer PDL. In the specification, the light emitting areas PXA-B, PXA-G, and PXA-R may each correspond to a pixel. Each light emitting element ED-a may be disposed in an opening OH defined by the pixel definition layer PDL and distinguished from each other.

In FIG. 4, the first to third light emitting areas PXA-B, PXA-G, and PXA-R are shown to have a rectangular shape in a plan view, but embodiments are not limited thereto. In a plan view, the first to third light emitting areas PXA-B, PXA-G, and PXA-R may have different shapes such as a rhombus or a pentagon. In an embodiment, the first to third light emitting areas PXA-B, PXA-G, and PXA-R may each have a rectangular shape with rounded corner regions.

In FIG. 4, the second light emitting area PXA-G may be arranged in the first row, and the first light emitting area PXA-B and the third light emitting area PXA-R may be arranged in the second row. However, this is only an example, and the arrangement of the first to third light emitting areas PXA-B, PXA-G, and PXA-R may vary. For example, the first to third light emitting areas PXA-B, PXA-G, and PXA-R may be arranged in a same row.

One of the first to third light emitting areas PXA-B, PXA-G, and PXA-R may emit first color light, another may emit second color light that is different from the first color light, and the remaining one may emit third color light that is different from the first color light and the second color light. In an embodiment, the first light emitting area PXA-B may provide first light that corresponds to a portion of a source light. For example, the third light emitting area PXA-R may emit red light, the second light emitting area PXA-G may emit green light, and the first light emitting area PXA-B may emit blue light.

In the display area DA, a bank well area BWA may be defined. The bank well area BWA may be an area that is formed for preventing defects which may occur during a printing process of light control patterns CCP-B, CCP-G, and CCP-R included in a light conversion layer CCL, which will be explained later. The bank well area BWA may be an area that is formed by removing a portion of a partition wall part BK. In FIG. 4, two bank well areas BWA that are formed adjacent to the second light emitting area PXA-G are shown as an example. However, embodiments are not limited thereto, and the shape and arrangement of the bank well areas BWA may vary.

Referring to FIG. 5, a display device DD may include a display panel DP and a light control layer PP disposed on the display panel DP. The light control layer PP may include a light conversion layer CCL disposed on the display panel DP. The light control layer PP may further include a color filter layer CFL. The color filter layer CFL may be disposed between a base layer BL and the light conversion layer CCL.

In an embodiment, the display panel DP may be an emission type display panel. For example, the display panel DP may be an organic electroluminescence display panel or a quantum dot light emitting display panel.

The display panel DP may include a base substrate BS, a circuit layer DP-CL provided on the base substrate BS, and a display element layer DP-EL.

The display element layer DP-EL may include a light emitting element ED-a as a display element. The light emitting element ED-a may produce a source light as described above, and may include an emission layer that overlaps a first light emitting area PXA-B, a second light emitting area PXA-G, and a third light emitting area PXA-R.

The display element layer DP-EL may include a pixel definition layer PDL. The pixel definition layer PDL may include an organic layer or an inorganic layer. At least a portion of the light emitting element ED-a may be disposed in an opening OH defined in the pixel definition layer PDL.

The pixel definition layer PDL may be formed of a polymer resin. For example, the pixel definition layer PDL may include a polyacrylate-based resin or a polyimide-based resin. The pixel definition layer PDL may include an inorganic material, in addition to the polymer resin. The pixel definition layer PDL may include a light absorbing material or may include a black pigment or a black dye. A pixel definition layer PDL that includes the black pigment or the black dye may form a black pixel definition layer. In forming the pixel definition layer PDL, carbon black or the like may be used as the black pigment or the black dye, but embodiments are not limited thereto.

The pixel definition layer PDL may be formed of an inorganic material. For example, the pixel definition layer PDL may include silicon nitride (SiNₓ), silicon oxide (SiOₓ), silicon oxynitride (SiOₓN_{y}), or the like. The pixel definition layer PDL may define the light emitting areas PXA-B, PXA-G, and PXA-R. The light emitting areas PXA-B, PXA-G, and PXA-R and the peripheral area NPXA may be separated from each other by the pixel defining layer PDL.

The display element layer DP-EL may include the light emitting element ED-a, and the light emitting element ED-a may include a first electrode EL1, a second electrode EL2, and multiple layers OL disposed between the first electrode EL1 and the second electrode EL2. The layers OL may include a hole transport region, an emission layer, and an electron transport region. An encapsulation layer TFE may be disposed on the light emitting element ED-a.

In the light emitting element ED-a included in the display panel DP, the emission layer may include a host and a dopant, which may be organic electroluminescence light emitting materials, or the emission layer may include the above-described quantum dots according to an embodiment. In the display panel DP according to an embodiment, the light emitting element ED-a may emit blue light.

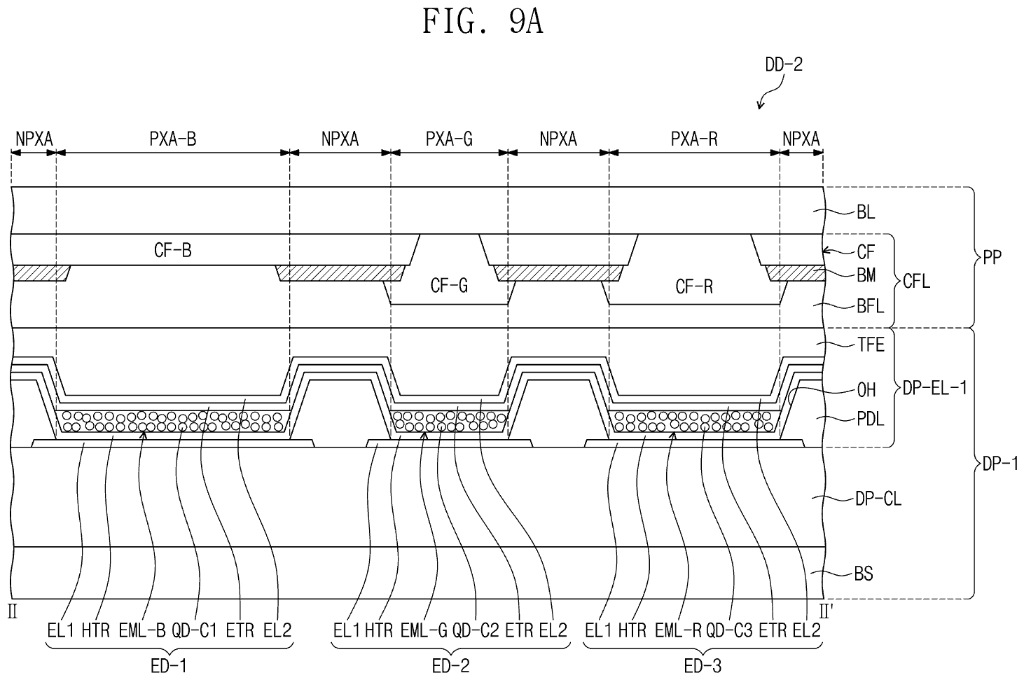

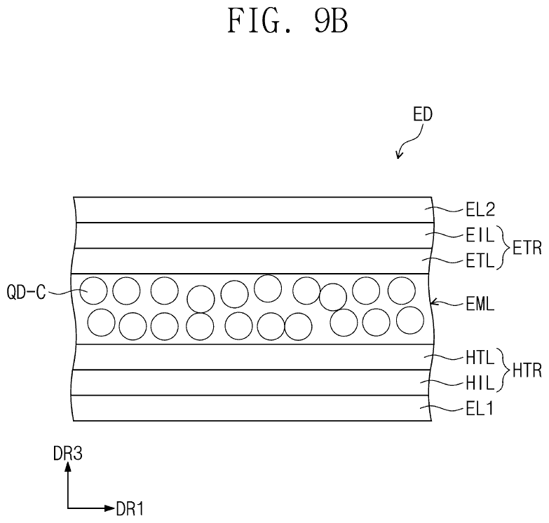

In the light emitting element ED-a included in the display panel DP according to an embodiment, the hole transport region and the electron transport region may respectively be the same as a hole transport region and an electron transport region that will be explained below with reference to FIG. 9A.

The encapsulation layer TFE may cover the light emitting element ED-a. The encapsulation layer TFE may be formed of a single layer or of multiple layers. The encapsulation layer TFE may be a thin film encapsulation layer. The encapsulation layer TFE may protect the light emitting element ED-a. The encapsulation layer TFE may cover the light emitting element ED-a and may be disposed to fill the opening OH.

The light control layer PP may be disposed on the encapsulation layer TFE. The light control layer PP may include a light conversion layer CCL, a color filter layer CFL, and a base layer BL.

The light conversion layer CCL may include multiple partition wall parts BK that may be separately disposed, and light control parts CCP-B, CCP-G, and CCP-R disposed between the partition wall parts BK. The partition wall part BK may include a polymer resin and a liquid repellent additive. The partition wall part BK may include a light absorbing material, or may include a black pigment or a black dye. For example, the partition wall part BK may include the black pigment or the black dye so as to form a black partition wall part. In forming the black partition wall part, carbon black or the like may be used as the black pigment or the black dye, but embodiments are not limited thereto.

The light control parts CCP-B, CCP-G, and CCP-R may be disposed in the openings OH defined in the partition wall part BK, and at least a portion of the light control parts CCP-B, CCP-G, and CCP-R may change the optical properties of a source light.

The light conversion layer CCL may include a first light control part CCP-B that transmits first light which is source light, a second light control part CCP-G including a first quantum dot complex QD-C2a that converts the first light into second light, and a third light control part CCP-R including a second quantum dot complex QD-C3a that transmits the first light into third light. The second light may have a wavelength range that is longer than the first light, and the third light may have a wavelength range that is longer than the first light and the second light. For example, the first light may be blue light, the second light may be green light, and the third light may be red light.

The first light control part CCP-B of the light conversion layer CCL may not include a quantum dot complex. However, embodiments are not limited thereto, and the first light control part CCP-B of the light conversion layer CCL may include a quantum dot complex. The quantum dot complex included in the first light control part CCP-B may emit blue light, which is the first color light.

At least one of the quantum dot complexes QD-C2a and QD-C3a, in the light control parts CCP-B, CCP-G, and CCP-R may be a quantum dot complex according to embodiments, which will be explained later. For example, the first quantum dot complex QD-C2a may be a quantum dot complex according to an embodiment, which will be explained later. However, embodiments are not limited thereto, and the first and second quantum dot complexes QD-C2a and QD-C3a may each be a quantum dot complex according to an embodiment, which will be explained later.

In an embodiment, the first and second quantum dot complexes QD-C2a and QD-C3a respectively included in the second and third light control parts CCP-G and CCP-R may include quantum dots that include different core materials. In another embodiment, the quantum dots included in the first and second quantum dot complexes QD-C2a and QD-C3a may include a same core material.

In an embodiment, the first and second quantum dot complexes QD-C2a and QD-C3a may include quantum dots having different diameters from each other. For example, the first quantum dot complex QD-C2a used in the second light control part CCP-G which emits light in a relatively shorter wavelength range may include quantum dots having a relatively smaller average diameter, as compared to the second quantum dot complex QD-C3a of the third light control part CCP-R which emits light in a relatively longer wavelength range.

In the specification, an average diameter corresponds to an arithmetic mean value of the diameters of a set of quantum dot particles. The diameter of the quantum dot particles may be a mean value of the widths of the cross-sections of the quantum dot particles.

The relationship of the average diameters of the first and second quantum dot complexes QD-C2a and QD-C3a is not limited to what is described above. For example, the sizes of the quantum dots included in the first and second quantum dot complexes QD-C2a and QD-C3a included in the light control parts CCP-G and CCP-R may be different. For example, the average diameter of the quantum dots of two quantum dot complexes selected from the first and second quantum dot complexes QD-C2a and QD-C3a may be similar, and the remainder may be different.

The light control parts CCP-B, CCP-G, and CCP-R may each further include a base resin that disperses the quantum dot complexes QD-C2a and QD-C3a. The base resin is a medium in which the quantum dot complexes QD-C2a and QD-C3a are dispersed, and may be composed of various resin compositions which may be referred to as a binder. For example, the base resin may include an acrylic resin, a methacrylic resin, a urethane-based resin, a fluorine-based resin, an epoxy-based resin, a vinyl-based resin, a polyester-based resin, a polyamide-based resin, a polyimide-based resin, a cellulose-based resin, a perylene-based resin, a silicon-based resin, or any combination thereof. The base resin may be a transparent resin. In the specification, an “A”-based resin is a resin that includes the “A” functional group.

The light conversion layer CCL may further include a filling layer CPL. The filling layer CPL may be disposed below the light control parts CCP-B, CCP-G, and CCP-R and the partition wall part BK. The filling layer CPL may be disposed between the encapsulation layer TFE and the light control parts CCP-B, CCP-G, and CCP-R. The filling layer CPL may block the penetration of humidity and/or oxygen (hereinafter, referred to as “humidity/oxygen”). The filling layer CPL may be disposed on the light control parts CCP-B, CCP-G, and CCP-R to block the exposure of the light control parts CCP-B, CCP-G, and CCP-R to humidity/oxygen. The filling layer CPL may include at least one inorganic layer.

In an embodiment shown in FIG. 5, the light control layer PP may include a color filter layer CFL. For example, the display device DD according to an embodiment may further include a color filter layer CFL disposed on the light emitting element ED-a of the display panel DP.

In the display device DD according to an embodiment, the light control layer PP may include a base layer BL and a color filter layer CFL.

The base layer BL may provide a base surface on which the color filter layer CFL or the like is disposed. The base layer BL may be a glass substrate, a metal substrate, a plastic substrate, or the like. However, embodiments are not limited thereto, and the base layer BL may include an inorganic layer, an organic layer, or a composite material layer.

The color filter layer CFL may include a light blocking part BM and a color filter part CF. The color filter part CF may include filters CF-B, CF-G, and CF-R. For example, the color filter layer CFL may include a first filter CF-B that transmits first light, a second filter CF-G that transmits second light, and a third filter CF-R that transmits third light. For example, the first filter CF-B may be a blue filter, the second filter CF-G may be a green filter, and the third filter CF-R may be a red filter.

The filters CF-B, CF-G, and CF-R may each include a polymer photosensitive resin and a pigment or a dye. The first filter CF-B may include a blue pigment or blue dye, the second filter CF-G may include a green pigment or green dye, and the third filter CF-R may include a red pigment or red dye.

However, embodiments are not limited thereto, and the first filter CF-B may not include a pigment or a dye. The first filter CF-B may include a polymer photosensitive resin and may not include a pigment or a dye. The first filter CF-B may be transparent. The first filter CF-B may be formed of a transparent photosensitive resin.

The light blocking part BM may be a black matrix. The light blocking part BM may include an organic light blocking material or an inorganic light blocking material, each including a black pigment or a black dye. The light blocking part BM may prevent light leakage and may distinguish the boundaries between adjacent filters CF-B, CF-G, and CF-R.

The color filter layer CFL may further include a buffer layer BFL. For example, the buffer layer BFL may protect the filters CF-B, CF-G, and CF-R. The buffer layer BFL may be an inorganic material layer including at least one of silicon nitride, silicon oxide, and silicon oxynitride. The buffer layer BFL may be formed of a single layer or of multiple layers.

In an embodiment shown in FIG. 5, the first filter CF-B of the color filter layer CFL is shown to overlap the second filter CF-G and the third filter CF-R, but embodiments are not limited thereto. For example, the first to third filters CF-B, CF-G, and CF-R may be separated from each other by the light blocking part BM so that they do not overlap each other. In an embodiment, the first to third filters CF-B, CF-G, and CF-R may be disposed to respectively correspond the blue light emitting area PXA-B, the green light emitting area PXA-G, and the red light emitting area PXA-R.

Although not shown in FIG. 5, in an embodiment, the display device DD may include a polarization layer (not shown) instead of the color filter layer CFL in the light control layer PP. The polarization layer (not shown) may block light that is external to the display panel DP. The polarization layer (not shown) may block a portion of the external light.

The polarization layer (not shown) may reduce light that is reflected at the display panel DP from the external light. For example, the polarization layer (not shown) may block the reflection of light that would otherwise enter the display device DD and exit again. The polarization layer (not shown) may be a circular polarizer with an anti-reflection function, or the polarization layer (not shown) may include a linear polarizer and a λ/4 phase retarder. The polarization layer (not shown) may be disposed on the base layer BL, or the polarization layer (not shown) may be disposed below the base layer BL.

FIG. 6A is a schematic diagram of a quantum dot complex according to an embodiment.

Referring to FIG. 6A, a quantum dot complex QD-C may include a scatterer SP and quantum dots QD1 and QD2, and may have a structure in which the scatterer SP and the quantum dots QD1 and QD2 are connected by ligands S-LD, LD1, and LD2. In the quantum dot complex QD-C according to an embodiment, the scatterer SP and the quantum dots QD1 and QD2 are provided such that the surfaces thereof are modified by aforementioned ligands. The scatterer ligand S-LD that is bonded to the scatterer SP and the ligands LD1 and LD2 that are respectively bonded to the surfaces of the quantum dots QD1 and QD2 may make chemical bonds, thereby providing a structure in which the scatter SP and the quantum dots QD1 and QD2 are connected.

The quantum dot complex QD-C may include first and second quantum dots QD1 and QD2, first and second ligands LD1 and LD2 that are respectively bonded to the surfaces of the first and second quantum dots QD1 and QD2, and a scatterer ligand S-LD bonded to the surface of the scatterer SP. In the quantum dot complex QD-C, the first and second ligands LD1 and LD2 may each make a chemical bond to the scatterer ligand S-LD. Through the chemical bonds of the first and second ligands LD1 and LD2 to the scatterer ligand S-LD, the first and second quantum dots QD1 and QD2 may each be connected to the scatterer SP. In the specification, the term “chemical bond” may be an ionic bond or a covalent bond. For example, the “chemical bond” may be a covalent bond.

The scatterer SP may be organic particles or inorganic particles that may scatter, refract, or diffuse light emitted from the quantum dots QD1 and QD2. The scatterer SP may include TiO₂, ZnO, Al₂O₃, SiO₂, hollow silica, or a combination thereof. For example, the scatterer SP may include one of TiO₂, ZnO, Al₂O₃, SiO₂, and hollow silica, or may include a mixture of two or more selected from TiO₂, ZnO, Al₂O₃, SiO₂, and hollow silica. In an embodiment, the scatterer SP may include inorganic particles. For example, the scatterer SP may be TiO₂.

The quantum dot complex QD-C may include quantum dots QD1 and QD2. The quantum dots QD1 and QD2 may include different core materials. Referring to FIG. 6A, the quantum dot complex QD-C may include the first quantum dot QD1 and the second quantum dot QD2, and a first core CR1 included in the first quantum dot QD1 and a second core CR2 included in the second quantum dot QD2 may include different materials from each other. For example, the first core CR1 may include a first semiconductor nanocrystal, and the second core CR2 may include a second semiconductor nanocrystal that is different from the first semiconductor nanocrystal.

An absorption wavelength of the cores included in the first and second quantum dots QD1 and QD2 may each independently be in a range of about 350 nm to about 530 nm. The absorption wavelength of the first core CR1 included in the first quantum dot QD1 may be in a range of about 350 nm to about 530 nm. The absorption wavelength of the second core CR2 included in the second quantum dot QD2 may be in a range of about 350 nm to about 530 nm. Accordingly, the first and second cores CR1 and CR2 may each absorb blue light in the above-described wavelength range and emit green light or red light.

In an embodiment, the first and second quantum dots QD1 and QD2 may each absorb first light, and may emit second light or third light, each having a wavelength that is longer than the first light. The first and second quantum dots QD1 and QD2 may each absorb first light and emit second light that has a wavelength longer than the first light. In another embodiment, the first and second quantum dots QD1 and QD2 may each absorb first light and emit third light that has a wavelength longer than the first light. In an embodiment, the first light may be blue light. For example, the first light may be blue light having a maximum emission wavelength in a range of about 430 nm to about 490 nm.

A maximum emission wavelength of the first quantum dot QD1 and a maximum emission wavelength of the second quantum dot QD2 may each independently be in a range of about 510 nm to about 550 nm. In an embodiment, the first and second quantum dots QD1 and QD2 may each emit light in a wavelength range of about 510 nm to about 550 nm. For example, the first and second quantum dots QD1 and QD2 may each independently emit green light with a maximum emission wavelength in a range of about 510 nm to about 550 nm. However, embodiments are not limited thereto, and the maximum emission wavelength of the first and second quantum dots QD1 and QD2 may each independently be in a range of about 630 nm to about 680 nm. For example, the first and second quantum dots QD1 and QD2 may each independently emit red light with a maximum emission wavelength in a range of about 630 nm to about 680 nm.

In an embodiment, the quantum dot complex QD-C may include two types of quantum dots QD1 and QD2 that include different core materials from each other and emitting a same color of light, and may increase external quantum efficiency (EQE) as compared to a quantum dot complex that includes a single type of quantum dot. Since the quantum dot complex QD-C includes two types of quantum dots QD1 and QD2 that include different core materials from each other and emitting a same color of light, an overlap between a maximum absorption wavelength spectrum and the maximum emission wavelength spectrum may decrease, and accordingly, a decrease of efficiency due to re-excitation and re-absorption by the quantum dots QD1 and QD2 may be prevented.

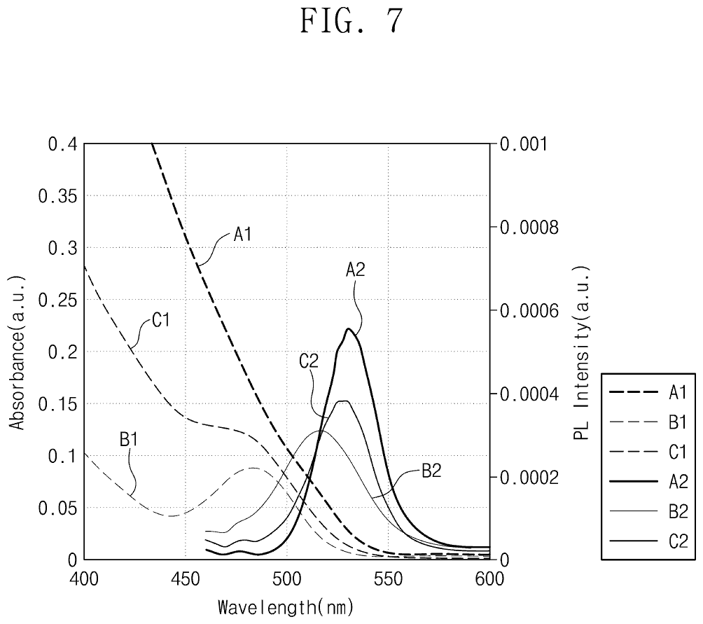

FIG. 7 is a graph showing absorption and emission spectrums of a light conversion pattern including a single type of quantum dot and a light conversion pattern including two types of quantum dots. In FIG. 7, “A1” corresponds to the absorption spectrum of light conversion pattern 1 including InP/ZnSeS quantum dots, “A2” corresponds to the emission spectrum of light conversion pattern 1 including InP/ZnSeS quantum dots, “B1” corresponds to the absorption spectrum of light conversion pattern 2 including AgInGaS/GaS quantum dots, “B2” corresponds to the emission spectrum of light conversion pattern 2 including AgInGaS/GaS quantum dots, “C1” corresponds to the absorption spectrum of light conversion pattern 3 including InP/ZnSeS quantum dots and AgInGaS/GaS quantum dots, and “C2” corresponds to the emission spectrum of light conversion pattern 3 including InP/ZnSeS quantum dots and AgInGaS/GaS quantum dots. The InP/ZnSeS quantum dot is a quantum dot that includes a core containing InP and a shell containing ZnSeS, and the AgInGaS/GaS quantum dot is a quantum dot that includes a core containing AgInGaS and a shell containing GaS.

Referring to FIG. 7, in the case of light conversion pattern 3 that includes two different types of quantum dots of InP/ZnSeS and AgInGaS/GaS, it can be confirmed that the overlap between the absorption wavelength spectrum and the emission wavelength spectrum was small, as compared to light conversion patterns 1 and 2 respectively including the single type of quantum dots of InP/ZnSeS and AgInGaS/GaS. If the overlap between the absorption wavelength spectrum and the emission wavelength spectrum increases, the re-excitation and re-absorption of quantum dots may increase, and the luminous efficiency of the quantum dots may degrade. However, if a light conversion pattern is formed using two different types of quantum dots, the overlap between the absorption wavelength spectrum and the emission wavelength spectrum may be configured to remain small, and accordingly, a reduction of efficiency due to the re-excitation and re-absorption of quantum dots may be prevented.

Referring to FIG. 6A, in an embodiment, the first and second quantum dots QD1 and QD2 may have a core-shell structure respectively including cores CR1 and CR2, and respectively including shells SL1 and SL2 that respectively surround the cores CR1 and CR2. The first quantum dot QD1 may include the first core CR1 and the first shell SL1 surrounding the first core CR1. The first shell SL1 may entirely surround the first core CR1. The second quantum dot QD2 may include the second core CR2 and the second shell SL2 surrounding the second core CR2. The second shell SL2 may entirely surround the second core CR2. The shells SL1 and SL2 may each serve as a protection layer for preventing the chemical deformation of the cores CR1 and CR2 and to maintain semiconductor properties and/or may serve as a charging layer for providing the quantum dots with electrophoretic properties. The shells SL1 and SL2 may each independently have a single-layered structure or a multilayered structure. However, embodiments are not limited thereto, and unlike what is shown in FIG. 6A, the shells SL1 and SL2 may be omitted from the quantum dots QD1 and QD2.

In an embodiment, if the quantum dots QD1 and QD2 include the shells SL1 and SL2, the shells SL1 and SL2 may include materials different from those of the cores CR1 and CR2. In the first quantum dot QD1, the first core CR1 and the first shell SL1 may include different materials from each other, and in the second quantum dot QD2, the second core CR2 and the second shell SL2 may include different materials from each other. For example, in the first quantum dot QD1, the first core CR1 may include a first semiconductor nanocrystal, and the first shell SL1 may include a third semiconductor nanocrystal, and the second core CR2 may include a second semiconductor nanocrystal, and the second shell SL2 may include a fourth semiconductor nanocrystal. In an embodiment, the first and second shells SL1 and SL2 may each independently include metal oxides or nonmetal oxides. The first and second shells SL1 and SL2 may each independently include a metal oxide, a nonmetal oxide, a semiconductor nanocrystal, or a combination thereof. In an embodiment, the third and fourth semiconductor nanocrystals may be the same as or different from each other.

In an embodiment, the shells SL1 and SL2 may each be formed of a single material, or may each be formed to have concentration gradient. For example, the shells SL1 and SL2 may each have a concentration gradient where, toward the cores CR1 and CR2, a concentration of the semiconductor nanocrystal present in the shells SL1 and SL2 decreases, and a concentration of the semiconductor crystals included in the cores CR1 and CR2 increases.

In an embodiment, the shells SL1 and SL2 may each have a multilayer structure. For example, the first and second shells SL1 and SL2 may each include a first sub-shell adjacent to the cores CR1 and CR2 and a second sub-shell separated from the cores CR1 and CR2, respectively. The second sub-shells may be respectively separated from the cores CR1 and CR2, with the first sub-shells respectively disposed therebetween. The first sub-shells may surround the cores CR1 and CR2, and the second sub-shells may surround the first sub-shells. The second sub-shells may entirely surround the first sub-shells. If the shells SL1 and SL2 included in the quantum dots QD1 and QD2 include the first sub-shells and the second sub-shells, the surfaces of the quantum dots QD1 and QD2 may be defined by the exterior of the second sub-shells. For example, the first sub-shells may be covered by the second sub-shells and may not form an external surface of the quantum dots QD1 and QD2.

In an embodiment, the cores CR1 and CR2 and the shells SL1 and SL2 may each independently include a semiconductor nanocrystal selected from a Group II-VI compound, a Group III-VI compound, a Group I-III-VI compound, a Group III-V compound, a Group III-II-V compound, a Group IV-VI compound, a Group IV element, a Group IV compound, or any combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as HgZnTeS, CdZnSeS, CdZnSeTe, CdZnSTe, CdHgSeS, CdHgSeTe, CdHgSTe, HgZnSeS, HgZnSeTe, and a mixture thereof; and any combination thereof.

Examples of a Group III-VI compound may include: a binary compound such as In₂S₃, and In₂Se₃; a ternary compound such as InGaS₃, and InGaSe₃; and any combination thereof.

Examples of a Group I-III-VI compound may include: a ternary compound such as AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂, and CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V compound may further include a Group II metal. Examples of a Group III-II-V compound may include InZnP or the like.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof. Examples of a Group IV element may include Si, Ge, and a mixture thereof. Examples of a Group IV compounds may include a binary compound such as SiC, SiGe, and a mixture thereof. In an embodiment, a binary compound, a ternary compound, or a quaternary compound may be present in a quantum dot at uniform concentration or at a partially different concentration distribution.

Examples of a metal oxide or a nonmetal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; a ternary compound such as MgAl₂O₄, CoFe₂O₄, NiFe₂O₄, and CoMn₂O₄; and any combination thereof, but embodiments are not limited thereto.

The quantum dot may have a full width at half maximum (FWHM) of an emission wavelength spectrum less than or equal to about 45 nm. For example, the quantum dot may have an FWHM of an emission wavelength spectrum less than or equal to about 40 nm. For example, the quantum dot may have an FWHM of an emission wavelength spectrum less than or equal to about 30 nm. When the FWHM of an emission wavelength spectrum is within any of these ranges, color purity or color reproducibility may be improved. Light emitted through a quantum dot may be emitted in all directions, so that a light viewing angle may be improved.

The quantum dot may have any form that is used in the related art. For example, the quantum dot may have a spherical shape, a pyramidal shape, a multi-arm shape, or a cubic shape, or the quantum dot may be in the form of a nanoparticle, a nanotube, a nanowire, a nanofiber, a nanoplate particles, etc.

In an embodiment, the color of light emitted by a quantum dot may be controlled according to a particle size of the quantum dot, and accordingly, the quantum dot may produce light of various colors such as blue light, red light, or green light. If the particle size of the quantum dot decreases, light in a short wavelength range may be emitted. For example, for quantum dots having a core of a same material, a particle size of the quantum dot emitting green light may be smaller than a particle size of the quantum dot emitting red light. For example, for quantum dots having a core of a same material, a particle size of the quantum dot emitting blue light may be smaller than a particle size of the quantum dot emitting green light. However, embodiments are not limited thereto, and for quantum dots having a core of a same material, particle size may be controlled depending on a material of the shell, a thickness of a shell, or the like.

In an embodiment, quantum dots having different core materials may emit various colors of light, such as blue light, red light, and green light.

Referring to FIG. 6A, in the quantum dot complex QD-C according to an embodiment, the first core CR1 may include a Group III-V compound, and the second core CR2 may include a Group I-III-VI compound. For example, the first core CR1 may include InP, and the second core CR2 may include AgInGaS. The quantum dot complex QD-C includes the first quantum dot QD1 including the first core CR1 containing the Group III-V compound and the second quantum dot QD2 including the second core CR2 containing the Group I-III-VI compound, and the quantum dot complex QD-C may have a high blue light absorption ratio.

In an embodiment, the first and second quantum dots QD1 and QD2 may each be non-Cd-based quantum dots. For example, the first and second quantum dots QD1 and QD2 may each not include cadmium (Cd).

In an embodiment, a diameter of the first and second quantum dots QD1 and QD2 may each independently be in a range of about 1 nm to about 10 nm. If the first and second quantum dots QD1 and QD2 each satisfy the above-described average particle diameter, characteristic behavior as quantum dots may be exhibited, and excellent dispersibility may be provided. By diversely selecting the average particle diameter of the quantum dots within the above-described range, the emission wavelength of the quantum dots and/or the semiconducting properties of the quantum dots may be changed in various ways.

The quantum dot complex QD-C may include first and second ligands LD1 and LD2 respectively bonded to the surfaces of the first and second quantum dots QD1 and QD2. The first ligand LD1 may be bonded to the surface of the first quantum dot QD1, and the second ligand LD2 may be bonded to the surface of the second quantum dot QD2. If the first quantum dot QD1 includes the first shell SL1 surrounding the first core CR1, the first ligand LD1 may be bonded to the surface of the first shell SL1 of the first quantum dot QD1. If the second quantum dot QD2 includes the second shell SL2 surrounding the second core CR2, the second ligand LD2 may be bonded to the surface of the second shell SL2 of the second quantum dot QD2.

The ligands LD1 and LD2 may respectively include head parts HD1 and HD2 bonded to the surfaces of the quantum dots QD1 and QD2, and tail parts TL1 and TL2 separated from the surface of the quantum dots QD1 and QD2 and bonded to the scatterer ligand S-LD. As shown in FIG. 6A, if the quantum dots QD1 and QD2 include the shells SL1 and SL2, respectively surrounding the cores CR1 and CR2, the ligands LD1 and LD2 may be bonded to the surfaces of the shells SL1 and SL2. For example, the first quantum dot QD1 may include the first core CR1 and the first shell SL1 surrounding the first core CR1, and the first ligand LD1 may be bonded to the surface of the first shell SL1. For example, the second quantum dot QD2 may include the second core CR2 and the second shell SL2 surrounding the second core CR2, and the second ligand LD2 may be bonded to the surface of the second shell SL2.

The head parts HD1 and HD2 may be respectively positioned at the ends of the ligands LD1 and LD2 and may respectively connect the quantum dots QD1 and QD2 with the remainder of the ligands LD1 and LD2. The tail parts TL1 and TL2 may be respectively positioned at the other ends of the ligands LD1 and LD2 and may respectively connect the ligands LD1 and LD2 with the scatterer ligand S-LD. The ligands LD1 and LD2 may further include connection parts CN1 and CN2 respectively disposed between the head parts HD1 and HD2 and the tail parts TL1 and TL2. For example, the ligands LD1 and LD2 may include the head parts HD1 and HD2, the connection parts CN1 and CN2 connected with the head parts HD1 and HD2, and the tail parts TL1 and TL2 connected with the connection parts CN1 and CN2. The connection parts CN1 and CN2 may be parts for increasing the dispersibility of the quantum dots QD1 and QD2.

As shown in FIG. 6A, the first ligand LD1 may include the first head part HD1 bonded to the surface of the first quantum dot QD1, and the first tail part TL1 separated from the surface of the first quantum dot QD1 and bonded to the scatterer ligand S-LD. The first ligand LD1 may further include the first connection part CN1 disposed between the first head part HD1 and the first tail part TL1 and connecting the first head part HD1 and the first tail part TL1. The second ligand LD2 may include the second head part HD2 bonded to the surface of the second quantum dot QD2, and the second tail part TL2 separated from the surface of the second quantum dot QD2 and bonded to the scatterer ligand S-LD. The second ligand LD2 may further include the second connection part CN2 disposed between the second head part HD2 and the second tail part TL2 and connecting the second head part HD2 and the second tail part TL2.

The scatterer SP may be connected with each of the first and second quantum dots QD1 and QD2. The scatterer ligand S-LD bonded to the surface of the scatterer SP may be connected with the first ligand LD1 bonded to the surface of the first quantum dot QD1 and connected with the second ligand LD2 bonded to the surface of the second quantum dot QD2.

The scatterer SP and the first and second quantum dots QD1 and QD2 may be connected with each other through the ligands. The scatterer ligand S-LD bonded to the surface of the scatterer SP and the first ligand LD1 bonded to the surface of the first quantum dot QD1 may make a chemical bond together so that the scatterer SP and the first quantum dot QD1 may be connected. The scatterer ligand S-LD bonded to the surface of the scatterer SP and the second ligand LD2 bonded to the surface of the second quantum dot QD2 may make a chemical bond together so that the scatterer SP and the second quantum dot QD2 may be connected.

In an embodiment, the scatterer ligand S-LD may include an end bonded to the scatterer SP, and another end separated from the scatterer SP and including a first functional group that may make a chemical bond with each of the first and second ligands LD1 and LD2. For example, the scatterer ligand S-LD may include a scatterer head part S-HD bonded to the surface of the scatterer SP and a scatterer tail part S-TL separated from the surface of the scatterer SP. The scatterer tail part S-TL may include the first functional group that may make a chemical bond with each of the first and second ligands LD1 and LD2. The scatterer ligand S-LD may further include a scatterer connection part S-CN that connects the scatterer head part S-HD and the scatterer tail part S-TL together.

In the quantum dot complex QD-C, the scatterer head part S-HD included in the scatterer ligand S-LD may make chemical bonds with cations or anions provided at the surface of the scatterer SP. If the scatterer head part S-HD includes one functional group for making a bond to the surface of the scatterer SP, the scatterer ligand S-LD may be a monodentate ligand. If the scatterer head part S-HD includes two functional groups for making bonds to the surface of the scatterer SP, the scatterer ligand S-LD may be a bidentate ligand. The scatterer head part S-HD may include a functional group for making a bond to the surface of the scatterer SP, so that the scatterer ligand S-LD may be effectively bonded to the scatterer SP. In an embodiment, the scatterer head part S-HD may be an amine group, a thiol group, a hydroxyl group, a dithioic acid group, a phosphine group, a phosphine oxide group, a catechol group, or a carboxyl group, but embodiments are not limited thereto.

In the quantum dot complex QD-C, the scatterer tail part S-TL included in the scatterer ligand S-LD may make chemical bonds with the first and second ligands LD1 and LD2. The scatterer tail part S-TL may include the first functional group making the chemical bonds with the first and second ligands LD1 and LD2. In an embodiment, the first functional group may include a reactive functional group that may make chemical bonds with the first and second ligands LD1 and LD2. The first functional group may include a nucleophilic functional group or an electrophilic functional group. For example, the first functional group may be a nucleophilic functional group including at least one of a thiol group, an amine group, a hydroxyl group, an azide group, and an oxetanyl group, or may be an electrophilic functional group including at least one of an alkenyl group, an alkynyl group, a carboxyl group, an acyl halide group, and a (meth)acrylate group. In an embodiment, the first functional group may include at least one of a thiol group, an amine group, a hydroxyl group, an azide group, and an oxetanyl group. For example, the first functional group may be one selected from a thiol group, an amine group, a hydroxyl group, an azide group, and an oxetanyl group.

In the quantum dot complex QD-C, if the scatterer ligand S-LD further includes the scatterer connection part S-CN connecting the scatterer head part S-HD and the scatterer tail part S-TL, the scatterer connection part S-CN may be an ethylene glycol group, a substituted or unsubstituted alkylene group of 1 to 30 carbon atoms, a substituted or unsubstituted alkenylene group of 2 to 30 carbon atoms, a substituted or unsubstituted divalent thio group, a substituted or unsubstituted divalent oxy group, a substituted or unsubstituted arylene group of 6 to 60 ring-forming carbon atoms, or a substituted or unsubstituted heteroarylene group of 2 to 60 ring-forming carbon atoms. However, embodiments are not limited thereto, and the scatterer connection part S-CN may be omitted from the scatterer ligand S-LD. In the specification, an “ethylene glycol group” may a group having a structure of —O(C₂H₄)ₘ—, wherein m may be an integer from 1 to 30.

In the quantum dot complex QD-C, the first and second head parts HD1 and HD2 respectively included in the first and second ligands LD1 and LD2 may make bonds with cations provided on the surfaces of the quantum dots QD1 and QD2. If the first and second head parts HD1 and HD2 each include one functional group for bonding to the surfaces of the quantum dots QD1 and QD2, the first and second ligands LD1 and LD2 may be monodentate ligands. If the first and second head parts HD1 and HD2 each include two functional groups for bonding to the surfaces of the quantum dots QD1 and QD2, the ligands may be bidentate ligands. The first and second head parts HD1 and HD2 each include a functional group for bonding to the surfaces of the quantum dots QD1 and QD2, so that the ligands LD1 and LD2 may be effectively bonded to the quantum dots QD1 and QD2. In an embodiment, the first and second head parts HD1 and HD2 may each independently be an amine group, a thiol group, a hydroxyl group, a dithioic acid group, a phosphine group, a phosphine oxide group, a catechol group, or a carboxyl group.

In the quantum dot complex QD-C, the first and second tail parts TL1 and TL2 respectively included in the first and second ligands LD1 and LD2 may each form a bond with the scatterer ligand S-LD. The first and second tail parts TL1 and TL2 may each include a functional group that makes a bond with the scatterer ligand S-LD. The first tail part TL1 included in the first ligand LD1 may include a second functional group making a chemical bond with the first functional group included in the scatterer ligand S-LD, and the second tail part TL2 included in the second ligand LD2 may include a third functional group making a chemical bond with the first functional group included in the scatterer ligand S-LD.

In an embodiment, the second and third functional groups may each independently be a nucleophilic functional group or an electrophilic functional group. For example, the second and third functional groups may each independently be: a nucleophilic functional group including at least one of a thiol group, an amine group, a hydroxyl group, an azide group, and an oxetanyl group; or an electrophilic functional group including at least one of an alkenyl group, an alkynyl group, a carboxyl group, an acyl halide group, and a (meth)acrylate group. If the first functional group includes a nucleophilic functional group, the second and third functional groups may each include an electrophilic functional group. If the first functional group includes an electrophilic functional group, the second and third functional groups may include a nucleophilic functional group.

In an embodiment, the second and third functional groups may each independently include at least one of an alkenyl group, an alkynyl group, a carboxyl group, an acyl halide group, and a (meth)acrylate group. For example, the second and third functional groups may each independently include at least one selected from an alkenyl group, an alkynyl group, a carboxyl group, an acyl halide group, and a (meth)acrylate group.

In the quantum dot complex QD-C, the first and second connection parts CN1 and CN2 included in the first and second ligands LD1 and LD2 may each independently be a substituted or unsubstituted alkylene group of 1 to 30 carbon atoms, a substituted or unsubstituted alkenylene group of 2 to 30 carbon atoms, a substituted or unsubstituted divalent thio group, a substituted or unsubstituted divalent oxy group, a substituted or unsubstituted arylene group of 6 to 60 ring-forming carbon atoms, or a substituted or unsubstituted heteroarylene group of 2 to 60 ring-forming carbon atoms.

The quantum dot complex QD-C may include the scatterer SP and the first and second quantum dots QD1 and QD2, and may have a structure in which the scatterer SP and the multiple quantum dots QD1 and QD2 are connected via chemical bonds between the scatterer ligand S-LD bonded to the scatterer SP and the ligands LD1 and LD2 bonded to the surfaces of the quantum dots QD1 and QD2. The quantum dot complex QD-C according to an embodiment includes two types of quantum dots QD1 and QD2 including different core materials that emit a same color of light, and external quantum efficiency may increase as compared to a quantum dot complex that includes only a single type of quantum dot. The quantum dot complex QD-C according to an embodiment may have a structure in which the scatterer SP and the first and second quantum dots QD1 and QD2 are connected via the ligands S-LD, LD1 and LD2, so that the dispersibility of the two different types of the quantum dots QD1 and QD2 may be improved to prevent the degradation of light absorption due to the agglomeration of particles. Since the scatterer SP may be connected with the first and second quantum dots QD1 and QD2, light that is not absorbed by the first and second quantum dots QD1 and QD2 may be scattered by the scatterer SP and may be readily absorbed by adjacent first and second quantum dots QD1 and QD2. Accordingly, a display device including the quantum dot complex QD-C according to an embodiment may show high luminous efficiency.

FIG. 6B is a schematic diagram of a structure of a quantum dot complex according to an embodiment. FIG. 6B shows a quantum dot complex according to another embodiment that is different from the quantum dot complex QD-C shown in FIG. 6A.

Referring to FIG. 6B, the quantum dot complex QD-C may include a first scatterer SP1 with the first scatterer ligand S-LD1 bonded to the surface thereof, that makes a chemical bond with the first ligand LD1 bonded to the surface of the first quantum dot QD1, and a second scatterer SP2 with the second scatterer ligand S-LD2 bonded to the surface thereof, that makes a chemical bond with the second ligand LD2 bonded to the surface of the second quantum dot QD2. In an embodiment, the quantum dot complex QD-C may include a first sub quantum dot complex QD-C1 having a structure in which the first scatterer SP1 and the first quantum dot QD1 are connected, and a second sub quantum dot complex QD-C2 having a structure in which the second scatterer SP2 and the second quantum dot QD2 are connected.

The first sub quantum dot complex QD-C1 may include the first scatterer SP1, the first quantum dot QD1, the first scatterer ligand S-LD1 bonded to the surface of the first scatterer SP1, and the first ligand LD1 bonded to the surface of the first quantum dot QD1. In the first sub quantum dot complex QD-C1, the first scatterer ligand S-LD1 and the first ligand LD1 may make a chemical bond. Through the chemical bond between the first scatterer ligand S-LD1 and the first ligand LD1, the first scatterer SP1 and the first quantum dot QD1 may be connected.

The second sub quantum dot complex QD-C2 may include the second scatterer SP2, the second quantum dot QD2, the second scatterer ligand S-LD2 bonded to the surface of the second scatterer SP2, and the second ligand LD2 bonded to the surface of the second quantum dot QD2. In the second sub quantum dot complex QD-C2, the second scatterer ligand S-LD2 and the second ligand LD2 may make a chemical bond. Through the chemical bond between the second scatterer ligand S-LD2 and the second ligand LD2, the second scatterer SP2 and the second quantum dot QD2 may be connected.

In an embodiment, the first and second scatterer ligands S-LD1 and S-LD2 may each include a first functional group that may make chemical bonds with the first and second ligands LD1 and LD2. The first scatterer ligand S-LD1 may include an end bonded to the first scatterer SP1, and another end that may be separated from the first scatterer SP1 and may make a chemical bond to the first ligand LD1. For example, as shown in FIG. 6B, the first scatterer ligand S-LD1 may include a first scatterer head part S-HD1 bonded to the surface of the first scatterer SP1, and a first scatterer tail part S-TL1 that is separated from the surface of the first scatterer SP1 and including the first functional group. The first scatterer ligand S-LD1 may further include a first scatterer connection part S-CN1 that connects the first scatterer head part S-HD1 and the first scatterer tail part S-TL1 together. The second scatterer ligand S-LD2 may include an end bonded to the second scatterer SP2, and another end that is separated from the second scatterer SP2 and may make a chemical bond with the second ligand LD2. The second scatterer ligand S-LD2 may include a second scatterer head part S-HD2 bonded to the surface of the second scatterer SP2 and a second scatterer tail part S-TL2 that is separated from the surface of the second scatterer SP2 and including the first functional group. The second scatterer ligand S-LD2 may further include a second scatterer connection part S-CN2 that connects the second scatterer head part S-HD2 and the second scatterer tail part S-TL2 together. In an embodiment, the first functional group included in the first scatterer ligand S-LD1 and the first functional group included in the second scatterer ligand S-LD2 may be different from each other or may be the same.

The explanation on the scatterer head part S-HD described with reference to FIG. 6A may be applied to the first and second scatterer head parts S-HD1 and S-HD2 in FIG. 6B. The explanation on the scatterer connection part S-CN described with reference to FIG. 6A may be applied to the first and second scatterer connection parts S-CN1 and S-CN2 in FIG. 6B.

In the quantum dot complex QD-C according to an embodiment, a weight ratio of the first sub quantum dot complex QD-C1 to the second sub quantum dot complex QD-C2 may be in a range of about 1:1 to about 2:1. In an embodiment, a sum of the amounts of the first quantum dots QD1, the first ligand LD1, the first scatterer SP1, and the first scatterer ligand S-LD1 may be defined as a first weight; a sum of the amounts of the second quantum dots QD2, the second ligand LD2, the second scatterer SP2, and the second scatterer ligand S-LD2 may be defined as a second weight; and a ratio of the first weight to the second weight may in a range of be about 1:1 to about 2:1. The sum of the amounts of the first quantum dots QD1, the first ligand LD1, the first scatterer SP1, and the first scatterer ligand S-LD1 may be an amount of the first sub quantum dot complex QD-C1, and the sum of the amounts of the second quantum dots QD2, the second ligand LD2, the second scatterer SP2, and the second scatterer ligand S-LD2 may be an amount of the second sub quantum dot complex QD-C2.

In the quantum dot complex QD-C according to an embodiment, the first sub quantum dot complex QD-C1 may include the first quantum dots QD1, and the first core CR1 included in the first quantum dot QD1 may include a Group III-V compound. In an embodiment, the second sub quantum dot complex QD-C2 may include the second quantum dots QD2, and the second core CR2 included in the second quantum dot QD2 may include a Group I-III-VI compound. For example, the first core CR1 may include InP, and the second core CR2 may include AgInGaS. If a weight ratio of the first sub quantum dot complex QD-C1 including the first core CR1 containing a Group III-V compound to the second sub quantum dot complex QD-C2 including the second core CR2 containing a Group I-III-VI compound is within a range of about 1:1 to about 2:1, high external quantum efficiency may be exhibited, a high blue light absorption ratio may be exhibited, and thus, light efficiency of the quantum dot complex QD-C may be improved.

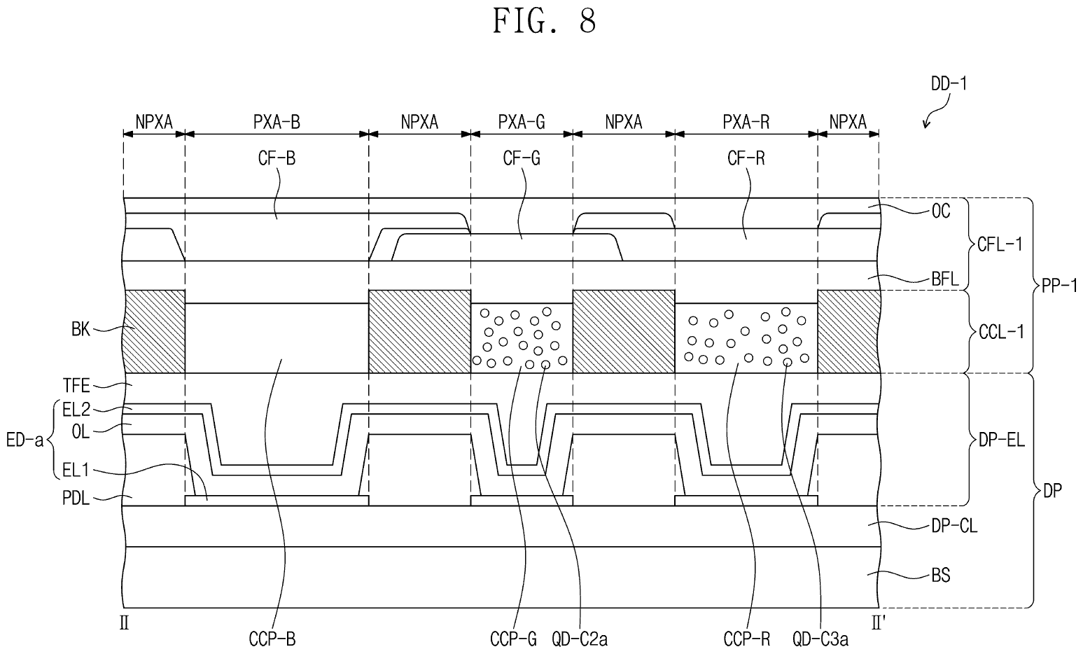

FIG. 8 is a schematic cross-sectional view of a display device DD-1 according to another embodiment. FIG. 8 shows a portion corresponding to virtual line II-II′ in FIG. 4. Hereinafter, in the explanation on the display device with reference to FIG. 8, the same components as explained above will be provided with the same reference symbols, and a detailed explanation thereof will not be repeated.

The display device DD-1 as shown in FIG. 8 may be different from the display device DD shown in FIG. 5 at least in that a base layer BL is omitted.

Referring to FIG. 8, the display device DD-1 may include a display panel DP and a light control layer PP-1 disposed on the display panel DP. The light control layer PP-1 may include a light conversion layer CCL-1 and a color filter layer CFL-1 disposed on the light conversion layer CCL-1.

The display device DD-1 shown in FIG. 8 may include a same display panel DP as shown in FIG. 5. The partition wall part BK of the light conversion layer CCL-1 may be disposed on an encapsulation layer TFE. The partition wall part BK may be disposed (e.g., directly disposed) on the encapsulation layer TFE. Different from the display device DD shown in FIG. 5, in the display device DD-1 according to an embodiment, a partition wall part BK, a first light control part CCP-B, a second light control part CCP-G, and a third light control part CCP-R may each be disposed on the encapsulation layer TFE. The partition wall part BK, the first light control part CCP-B, the second light control part CCP-G, and the third light control part CCP-R may each be disposed in the openings OH.

In an embodiment, the color filter layer CFL-1 may be disposed on the light conversion layer CCL-1. The color filter layer CFL-1 may include filters CF-B, CF-G, and CF-R, and an overcoat layer OC that covers the filters CF-B, CF-G, and CF-R. The color filter layer CFL-1 may include a first filter CF-B that overlaps a first light emitting area PXA-B, a second filter CF-G that overlaps a second light emitting area PXA-G, and a third filter CF-R that overlaps a third light emitting area PXA-R. The color filter layer CFL-1 included in the display device DD-1 shown in FIG. 8 may not include a light blocking part BM, which is different from the color filter layer CFL included in the display device DD shown in FIG. 5.

The first filter CF-B, the second filter CF-G, and the third filter CF-R may define the first light emitting area PXA-B, the second light emitting area PXA-G, the third light emitting area PXA-R, and a peripheral area NPXA. An area in which two or more filters among the first filter CF-B, the second filter CF-G, and the third filter CF-R overlap may be defined as the peripheral area NPXA. In the first light emitting area PXA-B, the second light emitting area PXA-G, and the third light emitting area PXA-R, only a corresponding filter among the first filter CF-B, the second filter CF-G, and the third filter CF-R may be disposed. However, embodiments are not limited thereto, and the display device DD-1 shown in FIG. 8 may further include a light blocking part BM (see FIG. 5) that distinguishes the boundaries between the filters CF-B, CF-G, and CF-R. If the light blocking part BM (FIG. 5) is further included, the peripheral area NPXA may be defined as an area in which the light blocking part BM (see FIG. 5) is disposed.

The overcoat layer OC may be an organic layer that protects the filters CF-R, CF-G, and CF-B. The overcoat layer OC may include a photo-curable organic material or a thermo-curable organic material. However, embodiments are not limited thereto, and the overcoat layer OC may include an inorganic material.

The color filter layer CFL-1 may further include a buffer layer BFL. The buffer layer BFL may be disposed between the light conversion layer CCL-1 and the filter layers CF-B, CF-G, and CF-R.

FIG. 9A is a schematic cross-sectional view of a display device DD-2 according to another embodiment. FIG. 9A shows a portion corresponding to virtual line II-II′ in FIG. 4. FIG. 9B is a schematic cross-sectional view of a light emitting element according to an embodiment.

Referring to FIG. 9A, a display device DD-2 may include a display panel DP-1 and a light control layer PP disposed on the display panel DP-1. The display panel DP-1 may include a base substrate BS, a circuit layer DP-CL disposed on the base substrate BS, and a display element layer DP-EL-1 disposed on the circuit layer DP-CL.

The display element layer DP-EL-1 may include light emitting elements ED-1, ED-2, and ED-3 emitting light in different wavelength ranges. For example, in an embodiment, the display device DD-2 may include a first light emitting element ED-1 emitting blue light, a second light emitting element ED-2 emitting green light, and a third light emitting element ED-3 emitting red light. However, embodiments are not limited thereto, and the first to third light emitting elements ED-1, ED-2, and ED-3 may emit light in a same wavelength range, or at least one of the first to third light emitting elements ED-1, ED-2, and ED-3 may emit light in a different wavelength range.

For example, the blue light emitting area PXA-B, the green light emitting area PXA-G, and the red light emitting area PXA-R of the display device DD-2 may respectively correspond to the first light emitting element ED-1, the second light emitting element ED-2, and the third light emitting element ED-3.

The display device DD-2 includes light emitting elements ED-1, ED-2, and ED-3, respectively including emission layers EML-B, EML-G, and EML-R respectively containing quantum dot complexes QD-C1, QD-C2, and QD-C3.

In the display device DD-2 a light control layer PP is disposed on the display panel DP-1. Although not shown in FIG. 9A, in an embodiment, the light control layer PP may be omitted from the display device DD-2.

The display panel DP-1 may include a base substrate BS, a circuit layer DP-CL provided on the base substrate BS, and a display element layer DP-EL-1, and the display element layer DP-EL-1 may include a pixel definition layer PDL, light emitting elements ED-1, ED-2, and ED-3 disposed in the pixel definition layer PDL, and an encapsulation layer TFE disposed on the light emitting elements ED-1, ED-2, and ED-3.

The first emission layer EML-B of the first light emitting element ED-1 may include a fourth quantum dot complex QD-C1. The fourth quantum dot complex QD-C1 may emit blue light that is first light.

The second emission layer EML-G of the second light emitting element ED-2 and the third emission layer EML-R of the third light emitting element ED-3 may respectively include a fifth quantum dot complex QD-C2 and a sixth quantum dot complex QD-C3. The fifth quantum dot complex QD-C2 and the sixth quantum dot complex QD-C3 may respectively emit green light that is second light and red light that is third light.

At least one of the fourth to sixth quantum dot complexes QD-C1, QD-C2, and QD-C3 may be a quantum dot complex according to an embodiment as described above. In an embodiment, the fifth quantum dot complex QD-C2 may be a quantum dot complex according to an embodiment as described above. However, embodiments are not limited thereto, and the fourth to sixth quantum dot complexes QD-C1, QD-C2, and QD-C3 may each be a quantum dot complex according to an embodiment as described above.

In an embodiment, the fourth to sixth quantum dot complexes QD-C1, QD-C2, and QD-C3 may include quantum dots having different diameters from each other. For example, the fourth quantum dot complex QD-C1 in the first light emitting element ED-1 that emits light in a relatively shorter wavelength range may include quantum dots having a relatively smaller average diameter, as compared to the fifth quantum dot complex QD-C2 of the second light emitting element ED-2 and the sixth quantum dot complex QD-C3 of the third light emitting element ED-3, which each emit light in relatively longer wavelength ranges.

The average diameter of the quantum dots included in the fourth to sixth quantum dot complexes QD-C1, QD-C2, and QD-C3 is not limited to the relationship as described above. The size of the quantum dots included in the fourth to sixth quantum dot complexes QD-C1, QD-C2, and QD-C3 may be different. The average diameter of the quantum dots included in two quantum dot complexes selected from the fourth to sixth quantum dot complexes QD-C1, QD-C2, and QD-C3 may be similar, and the average diameter of the quantum dots included in remaining quantum dot complex may be different.

In an embodiment, the pixel definition layer PDL may be formed from an inorganic material. For example, the pixel definition layer PDL may include silicon nitride (SiNₓ), silicon oxide (SiOₓ), silicon oxynitride (SiOₓN_{y}), or the like. The pixel definition layer PDL may define the light emitting areas PXA-B, PXA-G, and PXA-R. The light emitting areas PXA-B, PXA-G, and PXA-R and the peripheral area NPXA may be distinguished from each other by the pixel definition layer PDL.

The light emitting elements ED-1, ED-2, and ED-3 may each include a first electrode EL1, a hole transport region HTR, emission layers EML-B, EML-G, or EML-R, an electron transport region ETR, and a second electrode EL2. The first electrode EL1, the hole transport region HTR, the electron transport region ETR, and the second electrode EL2 may each be the same as described below with reference to FIG. 9B, except that the quantum dot complexes QD-C1, QD-C2, and QD-C3 respectively included in the emission layers EML-B, EML-G, and EML-R are different from each other. Although not shown in FIG. 9A, in an embodiment, the light emitting elements ED-1, ED-2, and ED-3 may each further include a capping layer between the second electrode EL2 and the encapsulation layer TFE.

The encapsulation layer TFE may cover the light emitting elements ED-1, ED-2, and ED-3. The encapsulation layer TFE may protect the light emitting elements ED-1, ED-2, and ED-3. The encapsulation layer TFE may cover the second electrode EL2 and may be disposed to fill the opening OH.

In FIG. 9A, the hole transport region HTR and the electron transport region ETR are each provided as a common layer that covers the pixel definition layer PDL, but embodiments are not limited thereto. In an embodiment, the hole transport region HTR and the electron transport region ETR may be disposed in the opening OH defined in the pixel definition layer PDL through a patterning process.

For example, if the hole transport region HTR, the electron transport region ETR, and the emission layers EML-B, EML-G, and EML-R are each provided by an inkjet printing method, the hole transport region HTR, the emission layers EML-B, EML-G, and EML-R, and the electron transport region ETR may be disposed within the opening OH defined in the pixel definition layer PDL. However, embodiments are not limited thereto, and the hole transport region HTR and the electron transport region ETR may not be patterned and may each be provided as a common layer that covers the pixel definition layer PDL as shown in FIG. 9A, irrespective of the manner by which each functional layer is provided.

In the display device DD-2 shown in FIG. 9A, the thicknesses of the emission layers EML-B, EML-G, and EML-R of the first to third light emitting elements ED-1, ED-2, and ED-3 are shown to be similar, but embodiments are not limited thereto. For example, in an embodiment, the thicknesses of the emission layers EML-B, EML-G, and EML-R of the first to third light emitting elements ED-1, ED-2, and ED-3 may be different from each other.

The display device DD-2 may further include a light control layer PP. The light control layer PP may control light that is reflected at the display panel DP from an external light. The light control layer PP may block a portion of an external light. The light control layer PP may have an anti-reflection function to minimize reflection of the external light. The light control layer PP may include a color filter layer CFL and a base layer BL disposed on the display element layer DP-EL-1. The color filter layer CFL and the base layer BL may each be the same as described above with reference to FIG. 5.

FIG. 9B is a schematic cross-sectional view of a light emitting element ED according to an embodiment. The light emitting element ED includes a first electrode EL1, a second electrode EL2 facing the first electrode EL1, and functional layers disposed between the first electrode EL1 and the second electrode EL2 and including an emission layer EML. At least one of the light emitting elements ED-1, ED-2, and ED-3 shown in FIG. 9A may have a structure according to the emitting element ED shown in FIG. 9B.

The functional layers may include a hole transport region HTR disposed between the first electrode EL1 and the emission layer EML, and an electron transport region ETR disposed between the emission layer EML and the second electrode EL2. Although not shown in the FIG. 9B, in an embodiment, the light emitting element ED may further include a capping layer disposed on the second electrode EL2.

The hole transport region HTR and the electron transport region ETR may each include sub-functional layers. For example, the hole transport region HTR may include a hole injection layer HIL and a hole transport layer HTL as sub-functional layers, and the electron transport region ETR may include an electron injection layer EIL and an electron transport layer ETL as sub-functional layers. However, embodiments are not limited thereto, and the hole transport region HTR may further include an electron blocking layer (not shown) as a sub-functional layer, and the electron transport region ETR may further include a hole blocking layer (not shown) as a sub-functional layer.

In the light emitting element ED according to an embodiment, the first electrode EL1 may have conductivity. The first electrode EL1 may include a metal alloy or a conductive compound. The first electrode EL1 may be an anode. In an embodiment, the first electrode EL1 may be a pixel electrode.

In the light emitting element ED according to an embodiment, the first electrode EL1 may be reflective electrode. However, embodiments are not limited thereto. For example, the first electrode EL1 may be a transmissive electrode or a transflective electrode. If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). In another embodiment, the first electrode EL1 may have multilayer structure including a reflective layer or a transflective layer formed of the above-described materials, and a transmissive conductive layer formed of indium tin oxide (ITO), indium zinc oxide (IZO), zinc oxide (ZnO), indium tin zinc oxide (ITZO), or the like. For example, the first electrode EL1 may include multiple metal layers or may have a stacked structure of ITO/Ag/ITO.

The hole transport region HTR may be provided on the first electrode EL1. The hole transport region HTR may include a hole injection layer HIL, a hole transport layer HTL, and the like. The hole transport region HTR may further include at least one of a hole buffer layer (not shown) and an electron blocking layer (not shown), in addition to the hole injection layer HIL and the hole transport layer HTL. The hole buffer layer (not shown) may compensate for a resonance distance according to a wavelength of light emitted from the emission layer EML and may increase light emission efficiency. Materials which may be included in the hole transport region HTR may be used as materials in the hole buffer layer (not shown). The electron blocking layer (not shown) may block electron injection from the electron transport region ETR to the hole transport region HTR.

The hole transport region HTR may have a structure consisting of a layer consisting of a single material, a structure consisting of a layer including different materials, or a structure including multiple layers including different materials. In embodiments, the hole transport region HTR may have a structure of a single layer including different materials, or may have a structure in which a hole injection layer HIL/hole transport layer HTL, a hole injection layer HIL/hole transport layer HTL/hole buffer layer (not shown), a hole injection layer HIL/hole buffer layer (not shown), a hole transport layer HTL/hole buffer layer (not shown), or a hole injection layer HIL/hole transport layer HTL/electron blocking layer (not shown) are stacked in its respective stated order from the first electrode EL1, but the structure of the hole transport region HTR is not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In an embodiment, the hole injection layer HIL may include a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris{N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzene sulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPD), triphenylamine-containing polyetherketone (TPAPEK), 4-isopropyl-4′-methyldiphenyliodonium [tetrakis(pentafluorophenyl)borate], dipyrazino[2,3-f:2′,3′-h]quinoxaline-2,3,6,7,10,11-hexacarbonitrile (HAT-CN), or the like.

In an embodiment the hole transport layer HTL may include materials of the related art. For example, the hole transport layer HTL may include carbazole derivatives such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPD), 4,4′-cyclohexylidene bis[N,N-bis(4-methylphenyl)benzeneamine](TAPC), 4,4′-bis[N,N′-(3-tolyl)amino]-3,3′-dimethylbiphenyl (HMTPD), 1,3-bis(N-carbazolyl)benzene (mCP), or the like.

A thickness of the hole transport region HTR may be in a range of about 5 nm to about 1,500 nm. For example, the thickness of the hole transport region HTR may be in a range of about 10 nm to about 500 nm. A thickness of the hole injection layer HIL may be in a range of about 3 nm to about 100 nm, and a thickness of the hole transport layer HTL may be in a range of about 3 nm to about 100 nm. For example, a thickness of the electron blocking layer EBL (not shown) may be in a range of about 1 nm to about 100 nm. If the thicknesses of the hole transport region HTR, the hole injection layer HIL, the hole transport layer HTL and the electron blocking layer (not shown) satisfy the above-described ranges, satisfactory hole transport properties may be achieved without substantial increase of a driving voltage.

The emission layer EML may be provided on the hole transport region HTR. The emission layer EML may include a quantum dot complex QD-C. The quantum dot complex QD-C included in the emission layer EML may include the scatterer SP (see FIG. 6A and FIG. 6B), the first and second quantum dots QD1 and QD2 (see FIG. 6A and FIG. 6B), the first and second ligands LD1 and LD2 (see FIG. 6A and FIG. 6B), and the scatterer ligand S-LD (see FIG. 6A and FIG. 6B). The quantum dot complex QD-C included in the emission layer EML of the light emitting element ED as shown in FIG. 9B may be the same as what is explained above with reference to FIG. 6A and FIG. 6B.

The emission layer EML may include multiple quantum dot complexes QD-C. The quantum dot complex QD-C included in the emission layer EML may be stacked so as to form a layer. In FIG. 9B, a quantum dot complex QD-C is shown to have a circular cross-section and arranged to form roughly two layers, but embodiments are not limited thereto. For example, an arrangement of the quantum dot complex QD-C may vary depending on the thickness of the emission layer EML, the shape of the quantum dot complex QD-C included in the emission layer EML, the average diameter of the scatterer and quantum dots included in the quantum dot complex QD-C, the type of ligand included in the quantum dot complex QD-C, or the like. In embodiments, the quantum dot complex QD-C in the emission layer EML may be arranged to form a single layer, or may be arranged to form multiple layers, such as two layers or three layers.

A maximum emission wavelength of light emitted from the emission layer EML may be in a range of about 510 nm to about 550 nm. For example, the emission layer EML may emit green light of a wavelength of about 510 nm to about 550 nm. However, embodiments are not limited thereto, and the emission layer EML may emit blue light or red light. A central wavelength of light emitted from the emission layer EML may be in a range of about 430 nm to about 490 nm. In another embodiment, the central wavelength of light emitted from the emission layer EML may be in a range of about 590 nm to about 650 nm.

In the light emitting element ED, the emission layer EML may include a host and a dopant. In an embodiment, the emission layer EML may include the quantum dot QD as a dopant material. In an embodiment, the emission layer EML may further include a host material.

In the light emitting element ED according to an embodiment, the emission layer EML may emit fluorescence. For example, the quantum dot complex QD-C may be used as a fluorescent dopant material.

In the light emitting element ED, the electron transport region ETR may be provided on the emission layer EML. The electron transport region ETR may include at least one of a hole blocking layer (not shown), an electron transport layer ETL, and an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single layer structure of an electron injection layer EIL or an electron transport layer ETL, or may have a single layer structure including an electron injection material and an electron transport material. In embodiments, the electron transport region ETR may have a single layer structure formed of different materials, or may have a structure in which an electron transport layer ETL/electron injection layer EIL, or a hole blocking layer (not shown)/electron transport layer ETL/electron injection layer EIL are stacked in its respective stated order from the emission layer EML, but embodiments are not limited thereto. A thickness of the electron transport region ETR may be in a range of about 20 nm to about 150 nm.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

If the electron transport region ETR includes an electron transport layer ETL, the electron transport region ETR may include an anthracene-based compound. However, embodiments are not limited thereto. The electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, bis[2-(diphenylphosphino)phenyl]ether oxide (DPEPO), 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), or a mixture thereof. A thickness of the electron transport layer ETL may be in a range of about 10 nm to about 100 nm. For example, the thickness of the electron transport layer ETL may be in a range of about 15 nm to about 50 nm. If the thickness of the electron transport layer ETL satisfies the any of the above-described ranges, satisfactory electron transport properties may be obtained without substantial increase of a driving voltage.

If the electron transport region ETR includes an electron injection layer EIL, the electron transport region ETR may include: a metal halide such as LiF, NaCl, CsF, RbCl, and RbI; a lanthanide metal such as Yb; a metal oxide such as Li₂O and BaO; or lithium quinolate (LiQ), but embodiments are not limited thereto. In another embodiment, the electron injection layer EIL may be formed of a mixture of an electron transport material and an insulating organometallic salt. For example, the organometallic salt may include metal acetates, metal benzoates, metal acetoacetates, metal acetylacetonates, or metal stearates. A thickness of the electron injection layer EIL may be in a range of about 0.1 nm to about 10 nm. For example, the thickness of the electron injection layer EIL may be in a range of about 0.3 nm to about 9 nm. If the thickness of the electron injection layer EIL satisfies any of the above-described ranges, satisfactory electron injection properties may be obtained without substantial increase of a driving voltage.

The electron transport region ETR may include a hole blocking layer (not shown) as described above. For example, the hole blocking layer (not shown) may include at least one of 2,9-dimethyl-4,7-diphenyl-1,10-phenanthroline (BCP), and 4,7-diphenyl-1,10-phenanthroline (Bphen). However, embodiments are not limited thereto.

The second electrode EL2 may be provided on the electron transport region ETR. The second electrode EL2 may be a cathode. The second electrode EL2 may be a common electrode. The second electrode EL2 may be a transmissive electrode, a transflective electrode, or a reflective electrode. If the second electrode EL2 is a transmissive electrode, the second electrode EL2 may include a transparent metal oxide such as indium tin oxide (ITO), indium zinc oxide (IZO), zinc oxide (ZnO), indium tin zinc oxide (ITZO), or the like.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In another embodiment, the second electrode EL2 may have a multilayered structure including a reflective layer or a transflective layer formed of the above-described materials and a transparent conductive layer formed using ITO, IZO, ZnO, ITZO, or the like.

Although not shown in the drawings, the second electrode EL2 may be electrically connected to an auxiliary electrode. If the second electrode EL2 is electrically connected to an auxiliary electrode, resistance of the second electrode EL2 may be reduced.

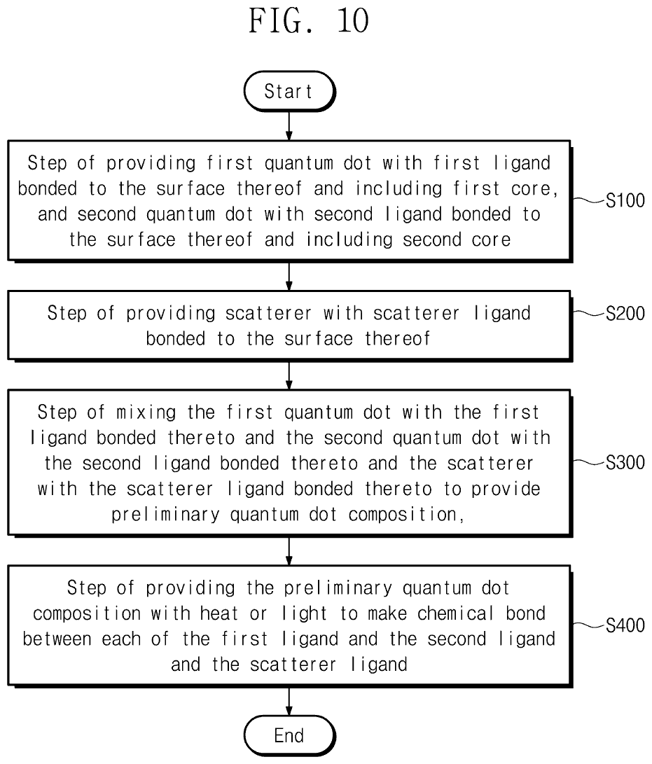

FIG. 10 is a flowchart of a method for manufacturing a quantum dot composition according to an embodiment.

Referring to FIG. 10, the method for manufacturing a quantum dot composition according to an embodiment may include a step of providing a first quantum dot with a first ligand bonded to a surface thereof and including a first core and providing a second quantum dot with a second ligand bonded to a surface thereof and including a second core that is different from the first core (S100), a step of providing a scatterer with a scatterer ligand bonded to a surface thereof (S200), a step of mixing the first quantum dot with the first ligand bonded thereto and the second quantum dot with the second ligand bonded thereto and the scatterer with the scatterer ligand bonded thereto to provide a preliminary quantum dot composition (S300), and a step of providing the preliminary quantum dot composition with heat or light to make a chemical bond between each of the first ligand and the second ligand and the scatterer ligand.

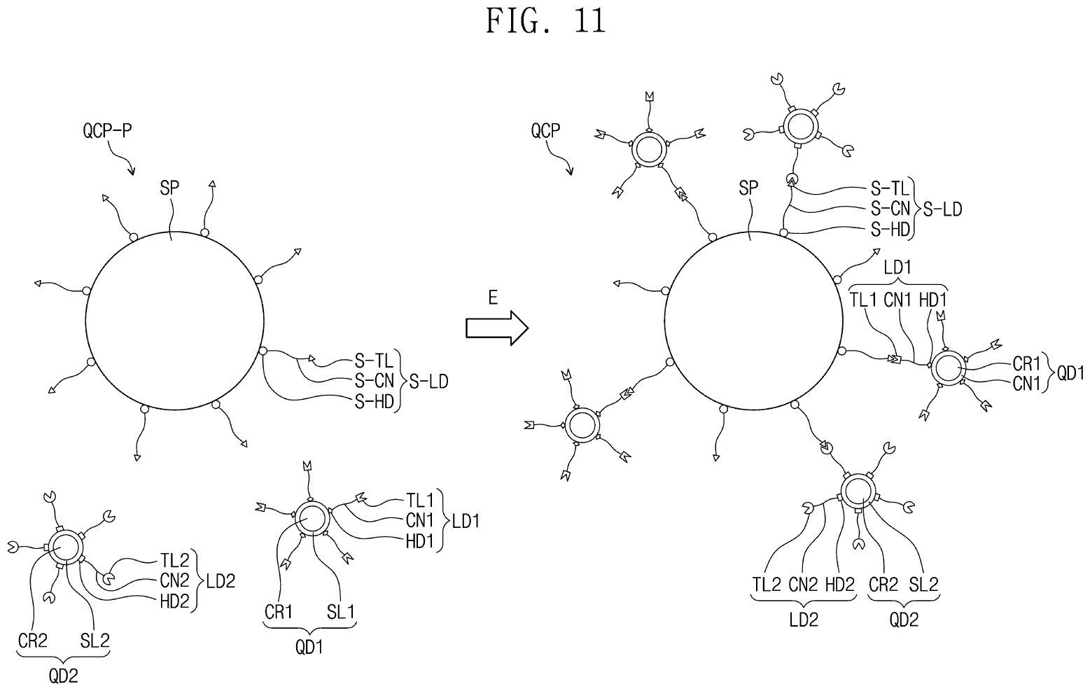

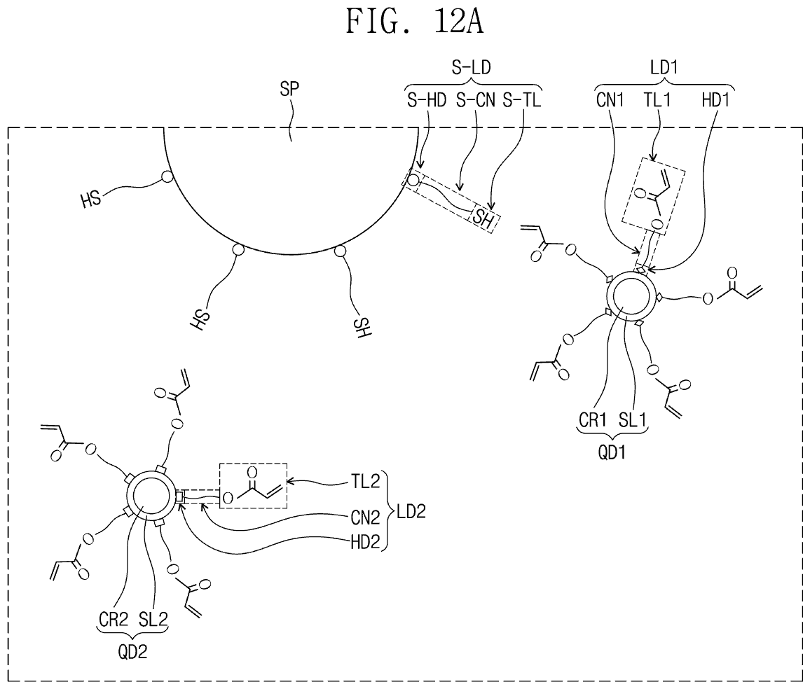

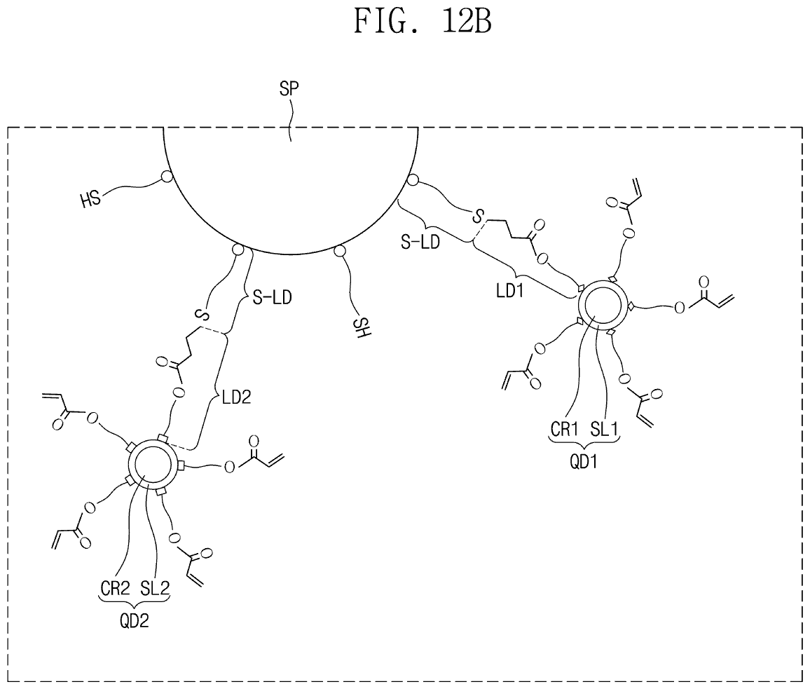

FIG. 11, FIG. 12A, and FIG. 12B are each a schematic cross-sectional view of steps of the method for manufacturing a quantum dot composition according to an embodiment. Hereinafter, in the explanation on the method for manufacturing a quantum dot composition according to an embodiment with reference to FIG. 11, FIG. 12A, and FIG. 12B, the same reference symbols are given for the same components as explained above, and the detailed explanation thereof will not be repeated.

Referring to FIG. 11, a first quantum dot QD1 with a first ligand LD1 bonded to the surface thereof and a second quantum dot QD2 with a second ligand LD2 bonded to the surface thereof may be provided. The first quantum dot QD1 and the second quantum dot QD2 may include different cores. The first quantum dot QD1 may include a first core CR1 and the second quantum dot QD2 may include a second core CR2 that is different from the first core CR1. As shown in FIG. 11, the first quantum dot QD1 may include a first shell SL1 surrounding the first core CR1, and the first ligand LD1 may be bonded to the surface of the first shell SL1. As also shown in FIG. 11, the second quantum dot QD2 may include a second shell SL2 surrounding the second core CR2, and the second ligand LD2 may be bonded to the surface of the second shell SL2.

The scatterer SP may be provided with a scatterer ligand S-LD bonded to the surface thereof. The scatterer SP may be provided in a state wherein the surface thereof is modified by the scatterer ligand S-LD.

As shown in FIG. 11, by mixing the first quantum dot QD1 with the first ligand LD1 bonded to the surface thereof, the second quantum dot QD2 with the second ligand LD2 bonded to the surface thereof, and the scatterer SP with the scatterer ligand S-LD bonded thereto, a preliminary quantum dot composition QCP-P may be provided. Although not shown in the drawings, the preliminary quantum dot composition QCP-P may further include a solvent that disperses the first quantum dots QD1, the second quantum dots QD2, and the scatterer SP.

By providing the preliminary quantum dot composition QCP-P with energy E, the first and second ligands LD1 and LD2 may make chemical bonds to the scatterer ligand S-LD. For example, by providing the preliminary quantum dot composition QCP-P with heat or light, the first and second ligands LD1 and LD2 may make chemical bonds to the scatterer ligand S-LD. By providing the heat or light, the first functional group of the scatterer ligand S-LD and the second functional group of the first ligand LD1 may react to make a chemical bond. By providing the heat or light, the first functional group of the scatterer ligand S-LD and the third functional group of the second ligand LD2 may react to make a chemical bond.

FIG. 12A and FIG. 12B are each a schematic diagram of a reaction step of a scatterer ligand S-LD with first and second ligands LD1 and LD2 in the quantum dot composition according to an embodiment.

In FIG. 12A and FIG. 12B, a step of making a chemical bond between of the first ligand LD1 and the scatterer ligand S-LD and between the second ligand LD2 and the scatterer ligand S-LD in the method for manufacturing a quantum dot composition according to an embodiment is shown as an illustration. In FIG. 12A and FIG. 12B, an embodiment is shown wherein the scatterer ligand S-LD includes a thiol group as the first functional group, the first ligand LD1 includes an acrylate group as the second functional group, and the second ligand LD2 includes an acrylate group as third functional group.

The first functional group included in the scatterer ligand S-LD and the second functional group included in the first ligand LD1 may react to form a chemical bond. As shown in FIG. 12A and FIG. 12B, the thiol group that is the first functional group included in the scatterer ligand S-LD and the acrylate group that is the second functional group included in the first ligand LD1 may react to form a chemical bond. The first functional group included in the scatterer ligand S-LD and the third functional group included in the second ligand LD2 may react to form a chemical bond. As shown in FIG. 12A and FIG. 12B, the thiol group that is the first functional group included in the scatterer ligand S-LD and the acrylate group that is the third functional group included in the second ligand LD2 may react to form a chemical bond.

In an embodiment, the chemical bond may be formed by a mechanism shown in Reaction 1. In Reaction 1, the formation of a chemical bond through the reaction of the scatterer ligand S-LD and the first ligand LD1 is shown as an illustration. The explanation of Reaction 1 may be similarly applied to a mechanism of forming the chemical bond through the reaction of the scatterer ligand S-LD and the second ligand LD2.

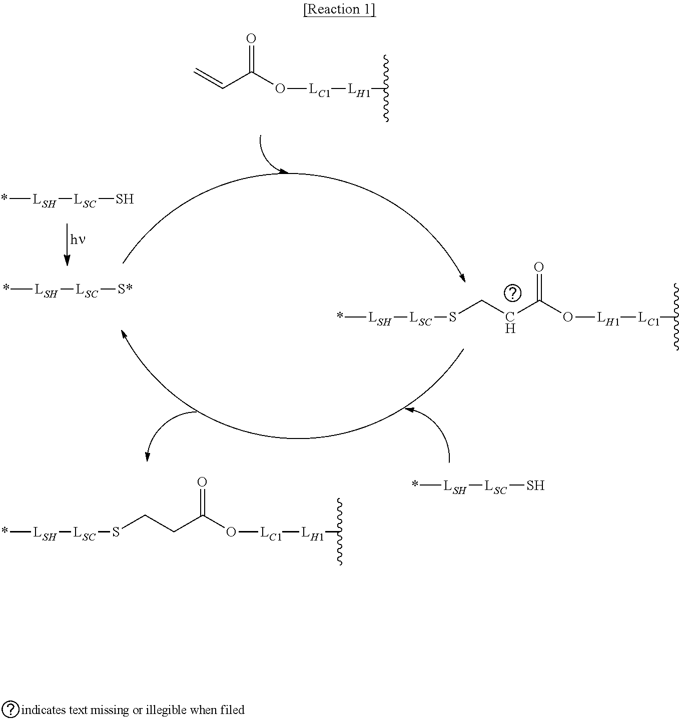

In Reaction 1, L_{SH} may correspond to the scatterer head part S-HD of the scatterer ligand S-LD, and L_{SC} may correspond to the scatterer connection part S-CN of the scatterer ligand S-LD. In Reaction 1, the symbol [symbol] represents a bond to the scatterer SP. In Reaction 1, L_{H1} may correspond to the first head part HD1 of the first ligand LD1, and L_{C1} may correspond to the first connection part CN1 of the first ligand LD1. In Reaction 1, the symbol

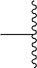

represents a bond to the first quantum dot QD1.

Referring to FIG. 12A, FIG. 12B, and Reaction 1 together, thiyl radicals may be formed from the thiol group included in the scatterer ligand S-LD by light (hv) provided to the preliminary quantum dot composition QCP-P. The thiyl radicals formed may react with carbon-carbon unsaturated bonds included in the first ligand LD1. Through the reaction between the thiyl radicals and the carbon-carbon unsaturated bonds, vinyl radicals having new sulfur-carbon bonds may be formed, and the reaction may be terminated by the vinyl radicals taking hydrogen atoms from another thiol group. In Reaction 1, the formation of a chemical bond by the radical addition reaction of the scatterer ligand S-LD and the first ligand LD1 is shown as an example, but embodiments are not limited thereto. The chemical bond between the scatterer ligand S-LD and the first ligand LD1 may be formed by a nucleophilic addition reaction or a nucleophilic substitution reaction, depending on the type of the functional group and reaction conditions.

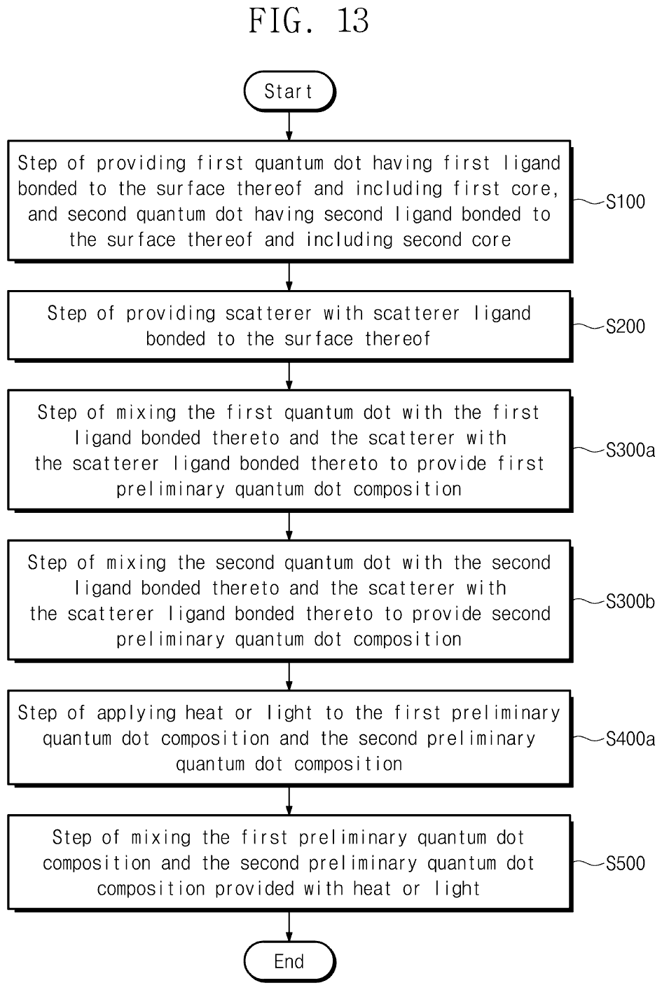

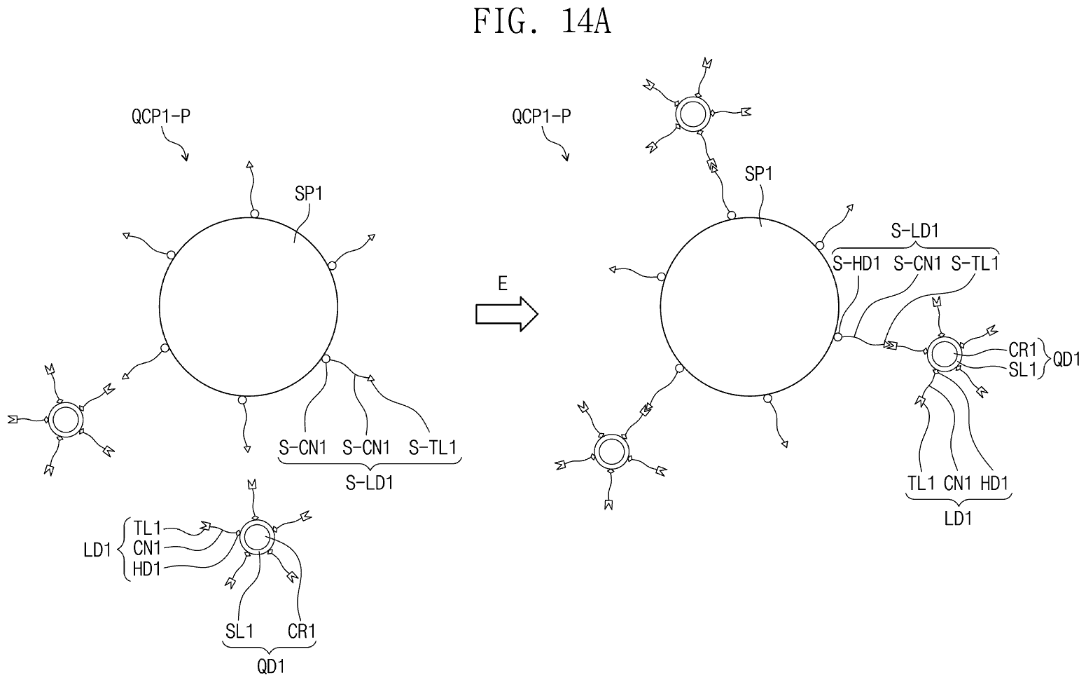

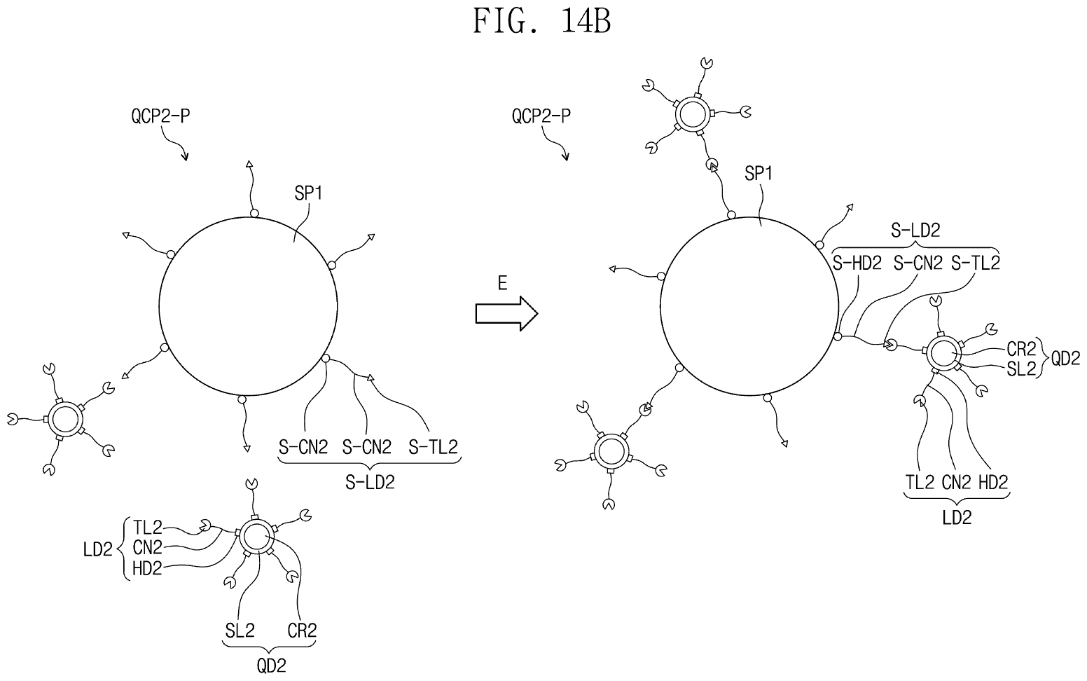

FIG. 13 is a flowchart of a method for manufacturing a quantum dot composition according to an embodiment. FIG. 14A and FIG. 14B are each a schematic diagram of a step of the method for manufacturing a quantum dot composition according to an embodiment. FIG. 13, FIG. 14A, and FIG. 14B illustrate another embodiment that is different from the method for manufacturing a quantum dot composition as shown in FIG. 10 to FIG. 12B. Hereinafter, the method for manufacturing a quantum dot composition according to an embodiment will be explained with reference to FIG. 13, FIG. 14A and FIG. 14B. The disclosure that has been explained above with reference to FIG. 10 to FIG. 12B will not be repeated, and the differing features will be explained.

Referring to FIG. 13, the method for manufacturing a quantum dot composition according to an embodiment may include a step of providing a first quantum dot having a first ligand bonded to the surface thereof and including a first core, and a second quantum dot having a second ligand bonded to the surface thereof and including a second core (S100), a step of providing a scatterer with a scatterer ligand bonded to the surface thereof (S200), a step of mixing the first quantum dot with the first ligand bonded thereto and the scatterer with the scatterer ligand bonded thereto to provide a first preliminary quantum dot composition (S300a), a step of mixing the second quantum dot with the second ligand bonded thereto and the scatterer with the scatterer ligand bonded thereto to provide a second preliminary quantum dot composition (S300b), a step of applying heat or light to the first preliminary quantum dot composition and to the second preliminary quantum dot composition (S400a), and a step of mixing the first preliminary quantum dot composition that has been provided with heat or light and the second preliminary quantum dot composition that has been provided with heat or light (S500). Thus, unlike the method for manufacturing a quantum dot composition as explained with reference to FIG. 10 to FIG. 12B, in the method for manufacturing a quantum dot composition according to the embodiment shown in FIG. 13, FIG. 14A, and FIG. 14B, after providing the first preliminary quantum dot composition by mixing the first quantum dots and the scatterer, and after providing the second preliminary quantum dot composition by mixing the second quantum dots and the scatterer through separate processes, chemical bonds between ligands may be formed by providing heat or light to the first preliminary quantum dot composition and to the second preliminary quantum dot composition.

Referring to FIG. 13 and FIG. 14A, the method for manufacturing a quantum dot composition according to an embodiment may include a step of providing a first preliminary quantum dot composition. The step of providing the first preliminary quantum dot composition (S300a) may include mixing the first quantum dot QD1 with the first ligand LD1 bonded to the surface thereof and the first scatterer SP1 with the first scatterer ligand S-LD1 bonded to the surface thereof. In the first preliminary quantum dot composition QCP1-P, the first quantum dot QD1 may be provided in a state wherein the surface thereof is modified by the first ligand LD1. In the first preliminary quantum dot composition QCP1-P, the first scatterer SP1 may be provided in a state wherein the surface thereof is modified by the first scatterer ligand S-LD1. Although not shown in the drawings, the first preliminary quantum dot composition QCP1-P may further include a solvent that disperses the first quantum dots QD1 and the first scatterer SP1.

The first preliminary quantum dot composition QCP1-P may be provided with energy (E) to make a chemical bond between the first ligand LD1 and the first scatterer ligand S-LD1. For example, by providing heat or light to the first preliminary quantum dot composition QCP1-P, the first ligand LD1 and the first scatterer ligand S-LD1 may make a chemical bond. By providing the heat or light, the first functional group of the first scatterer ligand S-LD1 and the second functional group of the first ligand LD1 may react to form a chemical bond. The above explanation of Reaction 1 may be similarly applied to the mechanism of forming the chemical bond through the reaction of the first ligand LD1 and the first scatterer ligand S-LD1.

Referring to FIG. 13 and FIG. 14B, the method for manufacturing a quantum dot composition according to an embodiment may include a step of providing a second preliminary quantum dot composition. The step of providing the second preliminary quantum dot composition (S300b) may include mixing the second quantum dots QD2 with the second ligand LD2 bonded to the surface thereof and the second scatterer SP2 with the second scatterer ligand S-LD2 bonded to the surface thereof. In the second preliminary quantum dot composition QCP2-P, the second quantum dot QD2 may be provided in a state wherein the surface thereof is modified by the second ligand LD2. In the second preliminary quantum dot composition QCP2-P, the second scatterer SP1 may be provided in a state wherein the surface thereof is modified by the second scatterer ligand S-LD2. Although not shown in the drawings, the second preliminary quantum dot composition QCP2-P may further include a solvent that disperses the second quantum dots QD1 and the second scatterer SP2.

The second preliminary quantum dot composition QCP2-P may be provided with energy (E) to make a chemical bond between the second ligand LD2 and the second scatterer ligand S-LD2. For example, by providing heat or light to the second preliminary quantum dot composition QCP2-P, the second ligand LD2 and the second scatterer ligand S-LD2 may make a chemical bond. By providing the heat or light, the second functional group of the second scatterer ligand S-LD2 and the third functional group of the second ligand LD2 may react to form a chemical bond. The above explanation of Reaction 1 may be similarly applied to the mechanism of forming the chemical bond through the reaction of the second ligand LD2 and the second scatterer ligand S-LD2.

A step of mixing the first preliminary quantum dot composition QCP1-P that has been provided with heat or light and the second preliminary quantum dot composition QCP2-P that has been provided with heat or light may be performed. Through the method for manufacturing a quantum dot composition as explained with reference to FIG. 13, FIG. 14A, and FIG. 14B, a quantum dot composition including quantum dot complexes QD-C1 and QD-C2 as shown in FIG. 6B may be produced.

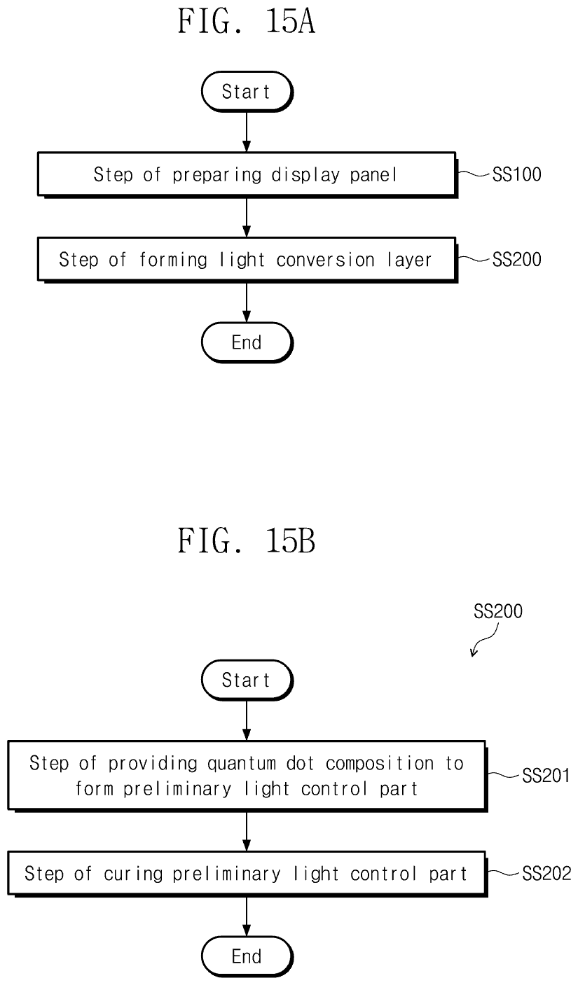

FIG. 15A is a flowchart of a method for manufacturing a display device according to an embodiment. FIG. 15B is a flowchart of steps of forming a light conversion layer according to an embodiment.

Referring to FIG. 15A, the method for manufacturing a display device according to an embodiment may include a step of preparing a display panel (SS100), and a step of forming a light conversion layer (SS200).

Referring to FIG. 15B, the step of forming a light conversion layer (SS200) according to an embodiment may include a step of providing a quantum dot composition to form a preliminary light control part (SS201), and a step of curing the preliminary light control part (SS202). In the display devices DD and DD-1 according to embodiments as described in FIG. 1 to FIG. 5 and FIG. 8, at least one of the light control parts CCP-B, CCP-G, and CCP-R included in the light conversion layer CCL may be formed through a step of forming a light conversion layer, which will be explained later.

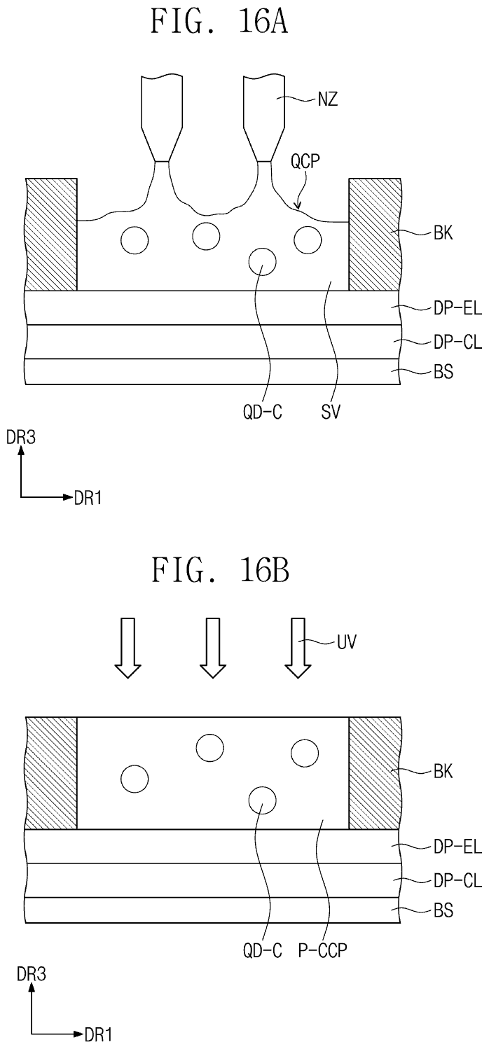

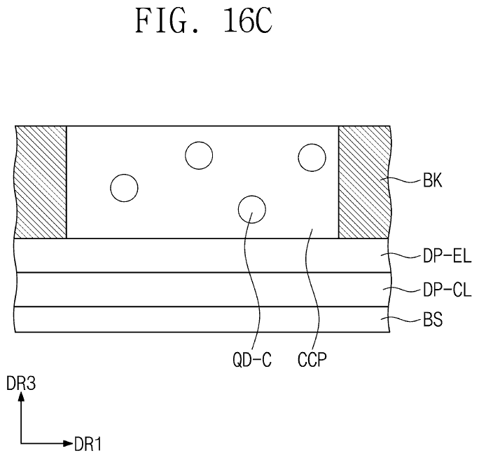

FIG. 16A to 16C are each a schematic cross-sectional view of steps in the method for manufacturing a display device according to an embodiment. In FIG. 16A to FIG. 16C, steps of forming a light conversion layer in the method for manufacturing of a display device according to an embodiment is shown in order. Hereinafter, in the explanation of the method for manufacturing a display device according to an embodiment with reference to FIG. 16A to FIG. 16C, the same reference symbols are provided for the same components as explained above, and detailed description thereof will not be repeated.

In the method for manufacturing a display device according to an embodiment, a step of preparing a display panel and a step of forming a light conversion layer on the display panel are included.

Referring to FIG. 16A, the step of forming a light conversion layer in the method for manufacturing a display device according to an embodiment may include a step of providing a quantum dot composition QCP on a base surface to form a light control part CCP (FIG. 16C). The quantum dot composition QCP shown in FIG. 16A may be the quantum dot composition produced through the method for producing quantum dots as explained with reference to FIG. 10 to FIG. 12B. In another embodiment, the quantum dot composition QCP shown in FIG. 16A may be the quantum dot composition produced through the method for producing quantum dots as explained with reference to FIG. 13 to FIG. 14B.

A method for providing the quantum dot composition QCP on the base surface is not particularly limited, and methods such as a spin coating method, a case method, a Langmuir-Blodgett (LB) method, an inkjet printing method, a laser printing method, and a laser induced thermal imaging (LITI) method may be used. In FIG. 16A, the quantum dot composition QCP may be applied onto the base surface via nozzles NZ, but embodiments are not limited thereto, and the quantum dot composition QCP may be provided onto the base surface by various methods.

In FIG. 16A to FIG. 16C, the base surface on which the quantum dot composition QCP is applied is shown as a display element layer DP-EL, but embodiments are not limited thereto. The quantum dot composition QCP may be applied on a base surface provided by the functional layers included in the light control layer PP (FIG. 5 and FIG. 8), for example, the base layer BL (FIG. 5 and FIG. 8) or the color filter layer CFL (FIG. 5 and FIG. 8). The method for manufacturing a display device of an embodiment may further include a step of patterning multiple partition wall parts BK on the base surface prior to the step of applying the quantum dot composition QCP. For example, as shown in FIG. 16A, if the base surface is the display element layer DP-EL, a step of patterning partition wall parts BK on the display element layer DP-EL may be further included prior to the step of applying the quantum dot composition QCP.

The quantum dot composition QCP may be disposed between partition wall parts BK. The quantum dot composition QCP may include a base resin SV and a quantum dot complex QD-C dispersed in the base resin SV. The quantum dot complex QD-C included in the quantum dot composition QCP may be the same as a quantum dot complex as explained above with reference to FIG. 6A and FIG. 6B or the like.

The base resin SV may include an acrylic resin, a methacrylic resin, a urethane-based resin, a fluorine-based resin, an epoxy-based resin, a vinyl-based resin, a polyester-based resin, a polyamide-based resin, a polyimide-based resin, a cellulose-based resin, a perylene-based resin, a silicon-based resin, or any combination thereof.

The quantum dot composition QCP of an embodiment may further include an additive. The additive may be selected from additives of the related art for controlling the physical properties required for the quantum dot composition QCP. For example, a dispersant, a light stabilizer, a crosslinking agent, an antioxidant, a chain transfer agent, a photosensitizer, a polymerization inhibitor, a leveling agent, a surfactant, an adhesion imparting agent, a plasticizer, a ultraviolet absorber, a storage stabilizer, an antistatic agent, an inorganic filler, a pigment, or a dye may be used, but embodiments are not limited thereto. The additive may be used singularly or as a combination of two or more thereof.

The quantum dot composition QCP according to an embodiment may further include an initiator. In the specification, an initiator may be a compound that is capable of initiating a radical polymerization by heat or light. The initiator may be a thermal initiator or a photo initiator.

The quantum dot composition QCP according to an embodiment may include a thermal initiator. Examples of a thermal initiator may include azobisisobutyronitrile, but embodiments are not limited thereto.

The quantum dot composition QCP according to an embodiment may include a photo initiator. The photo initiator may include triazine compounds, acetophenone compounds, benzophenone compounds, thioxanthone compounds, benzoin compounds, oxime ester compounds, aminoketone compounds, phosphine or phosphine oxide compounds, carbazole-based compounds, diketone compounds, sulfonium borate compounds, diazo-based compounds, biimidazole-based compounds, or any combination thereof, but embodiments are not limited thereto. If the quantum dot composition QCP includes multiple photo initiators, different photo initiators may be activated by ultraviolet light according to different central wavelengths.

In an embodiment, the photo initiator may be 2,2-dimethoxy-1,2-diphenylethan-1-one, 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one.

In an embodiment, the photo initiator may be 2-methyl-1[4-(methylthio)phenyl]-2-morpholinopropan-1-one), 2-benzyl-2-dimethylamino-1-(4-morpholinophenyl)-butanone-1, 2-dimethylamino-2-(4-methyl-benzyl)-1-(4-morpholin-4-yl-phenyl)-butan-1-one, 2,4,6-trimethylbenzoyl-diphenylphosphine oxide, 2,4,6-trimethylbenzoyl-diphenyl phosphinate, bis(2,4,6-trimethylbenzoyl)-phenylphosphineoxide, [1-(4-phenylsulfanylbenzoyl)heptylideneamino]benzoate, [1-[9-ethyl-6-(2-methylbenzoyl)carbazol-3-yl]ethylideneamino]acetate, bis(2,4-cyclopentadienyl)bis[2,6-difluoro-3-(1-pyrryl)phenyl]titanium(IV), or 2,4,6-trimethylbenzoyl-diphenyl phosphine oxide.

The quantum dot composition QCP may further include a solvent. In the step of forming the light control part CCP, the solvent may be removed. However, embodiments are not limited thereto, and a portion of the solvent may remain in the light control part CCP.

The solvent may be an organic solvent, or an inorganic solvent such as water. The organic solvent may include, for example, hexane, toluene, chloroform, dimethyl sulfoxide, octane, xylene, hexadecane, cyclohexylbenzene, triethylene glycol monobutyl ether, dimethyl formamide, decane, dodecane, hexadecene, cyclohexylbenzene, tetrahydronaphthalene, ethylnaphthalene, ethylbiphenyl, isopropylnaphthalene, diisopropylnaphthalene, diisopropylbiphenyl, xylene, isopropylbenzene, pentylbenznene, diisopropylbenzene, decahydronaphthalene, phenylnaphthalene, cyclohexyldecahydronaphthalene, decylbenzene, dodecylbenzene, octylbenzene, cyclohexane, cyclopentane, cycloheptane, methanol, ethanol, propanol, isopropanol, ethylene glycol, propylene glycol, or diethylene glycol, but embodiments are not limited thereto.

In an embodiment, a sum of the amount of the first quantum dots QD1 (FIG. 6A and FIG. 6B) and the amount of the second quantum dots QD2 (FIG. 6A and FIG. 6B) may be less than or equal to about 38 wt %, based on a total weight of the quantum dot composition QCP. The total weight of the quantum dot composition QCP may be a basis of 100 wt %. For example, a sum of the amount of the first quantum dots QD1 (FIG. 6A and FIG. 6B) and the amount of the second quantum dots QD2 (FIG. 6A and FIG. 6B) may be in a range of about 30 wt % to about 38 wt %. If the sum of the amount of the first quantum dots QD1 (FIG. 6A and FIG. 6B) and the amount of the second quantum dots QD2 (FIG. 6A and FIG. 6B) included in the quantum dot composition QCP satisfies the above-described range, the solution processability of the composition may be improved, and the luminous efficiency of a light control part CCP which will be formed later, may be sufficiently maintained.

In an embodiment, an amount of the scatterer SP (FIG. 6A and FIG. 6B) may be in a range of about 2 wt % to about 8 wt %, based on 100 wt % of a total weight of the quantum dot composition QCP. If the amount of the scatterer SP (FIG. 6A and FIG. 6B) is less than about 2 wt %, the dispersibility of the first and second quantum dots QD1 and QD2 may be reduced, and defects of reduced light absorption may arise due to the particle agglomeration or the like. If an amount of the scatterer SP (FIG. 6A and FIG. 6B) is greater than about 8 wt %, viscosity of the quantum dot composition QCP may increase excessively, and solution processability may be reduced.

Referring to FIG. 16A and FIG. 16B, the quantum dot composition QCP may form a preliminary light control part P-CCP. The preliminary light control part P-CCP formed through the quantum dot composition QCP may include a base resin SV and a quantum dot complex QD-C dispersed in the base resin SV.

FIG. 16B is a schematic cross-sectional view of a step of curing the preliminary light control part P-CCP (SS202) in the method for manufacturing a display device according to an embodiment. The step of curing the preliminary light control part P-CCP according to an embodiment may include a step of providing heat or light to the preliminary light control part P-CCP. In FIG. 16B, light (UV) is provided to the preliminary light control part P-CCP as an example, but embodiments are not limited thereto.

Referring to FIG. 16B and FIG. 16C, a light control part CCP may be formed by curing the preliminary light control part P-CCP. The light control part CCP may include the quantum dot complex QD-C. The quantum dot complex QD-C may be included and present in a formed light control part CCP. A display device DD including the light control part CCP formed from the quantum dot composition QCP may show improved luminous properties.

Although not shown in the drawings, the method for manufacturing a display device according to an embodiment may further include a step of baking the preliminary light control part P-CCP after the step of curing the preliminary light control part P-CCP. The step of baking the preliminary light control part P-CCP may be a step of providing heat at a temperature greater than or equal to about 50° C. The baking may be performed for removing the solvent included in the preliminary light control part P-CCP. For example, the step of baking the preliminary light control part P-CCP may be a step of providing heat at a temperature greater than or equal to about 100° C. to remove the solvent in the preliminary light control part P-CCP.

Although not shown in the drawings, at least one of the light emitting elements ED-1, ED-2, and ED-3 shown in FIG. 9A may be formed by a same method as the method of forming the light conversion layer. For example, the light emitting element ED shown in FIG. 9B may be formed by a same method as the method of forming the light conversion layer. For example, the method for manufacturing the light emitting element ED shown in FIG. 9B may include a step of forming a hole transport region HTR on a first electrode EL1, a step of forming an emission layer EML on the hole transport region HTR, a step of forming an electron transport region ETR on the emission layer EML, and a step of forming a second electrode EL2 on the electron transport region ETR, and the step of forming the emission layer EML may include a step of providing the above-described quantum dot composition QCP to form a preliminary emission layer, and a step of curing the preliminary emission layer as shown in FIG. 16A. The step of forming the preliminary emission layer and the step of curing the preliminary emission layer may be the same as what is explained above with reference to FIG. 16A to FIG. 16C regarding the step of forming the preliminary light control part and the step of curing the preliminary light control part.

Hereinafter, a quantum dot composition according to an embodiment will be explained in detail with reference to the Examples and the Comparative Examples. The Examples described below are only provided to assist in understanding the embodiments and disclosure, and the scope thereof is not limited thereto.

### Examples and Comparative Examples

### 1. Preparation of Quantum Dot Composition

### 1) Quantum Dot Composition 1

### (Synthesis of InP/ZnSeS Quantum Dots)

Indium acetate (10 mmol), zinc acetate (5 mmol), stearic acid (50 mmol) and 1-octadecene (50 ml) as a solvent were mixed and heated under vacuum at about 120° C. for about 2 hours to prepare a precursor solution. To the precursor solution, tris(trimethylsilyl)phosphine (5 mmol) was added under a nitrogen atmosphere at room temperature, followed by heating at about 300° C. for about 2 minutes. The temperature was reduced to prepare an InP core.

The InP core was purified using a mixture solution of toluene and acetone, and to the core dispersed in toluene, zinc oleate (12.6 mmol), trioctylphosphine selenide (10.2 mmol), trioctylphosphine sulfur (8 mmol), and trioctylamine were added and reacted at a temperature greater than or equal to about 320° C. for about 1 hour to form a ZnSeS (zinc selenide/sulfide) shell to synthesize InP/ZnSeS quantum dots.

### (Synthesis of AIGS/GaS Quantum Dots)

Indium iodide (4 mmol), gallium iodide (4 mmol), silver acetate (2.25 mmol) and oleylamine (50 ml) as a solvent were mixed and heated under vacuum at about 120° C. for about 2 hours to prepare a precursor solution. To the solution, dodecane thiol (16 mmol) was added, and the temperature was elevated to about 200° C. and heated for about 20 minutes under a nitrogen atmosphere. 10 ml of trioctylphosphine was added to quench the reaction to prepare an AIGS core.

After purifying the AIGS core using a mixture solution of toluene and acetone, gallium chloride (3 mmol) and dodecanethiol (9 mmol) were added to 50 ml of oleylamine and dissolved at about 80° C. for about 1 hour in vacuum. The AIGS core re-dispersed in toluene was added thereto, the temperature was elevated to about 280° C. to form a GaS (gallium sulfide) shell to synthesize AIGS/GaS quantum dots.

### (Synthesis of Quantum Dot-Ligand Bond)

About 34 wt % of the InP/ZnSeS quantum dots synthesized through the above-described processes were dissolved in cyclohexyl acetate, and about 20 wt % of mono-2-(acryloyloxy)ethyl succinate (MAS) in contrast to the quantum dots was added thereto, followed by heating at a temperature of about 70° C. for about 1 hour. The reaction mixture was purified using hexane to form a powder form to prepare ligand-bonded InP/ZnSeS quantum dots. Ligand-bonded AIGS/GaS quantum dots were synthesized by the same method.

### (Preparation of Quantum Dot Complex)

The ligand-bonded quantum dots InP/ZnSeS and scatterer ligand-bonded TiO₂ were mixed at a weight ratio of about 36:8 to prepare a first preliminary quantum dot composition. To the first preliminary quantum dot composition thus prepared, about 15 J of UV light at a wavelength of about 365 nm was irradiated to make a chemical bond between the quantum dot ligand bonded to the surface of the InP/ZnSeS quantum dot and the scattered ligand bonded to the surface of the scatterer TiO₂, and a first sub quantum dot complex was prepared.

A second sub quantum dot complex could be prepared by the same method as that of the first sub quantum dot complex. The ligand-bonded quantum dots AgInGaS/GaS and scatterer ligand-bonded scatterer TiO₂ were mixed at a weight ratio of about 36:8 to prepare a second preliminary quantum dot composition. To the second preliminary quantum dot composition thus prepared, about 15 J of UV light at a wavelength of about 365 nm was irradiated to make a chemical bond between the quantum dot ligand bonded to the surface of the AgInGaS/GaS quantum dot and the scattered ligand bonded to the surface of the scatterer TiO₂, and a second sub quantum dot complex was prepared.

The scatterer ligand used in the Examples and Comparative Examples used thiol (polyethylene glycol) carboxylic acid having a structure of S1. In Structure S1, m is 12.

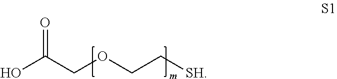

### (Preparation of Quantum Dot Composition)

The first sub quantum dot complex and the second sub quantum dot complex, prepared in the step of preparing the quantum dot complex were mixed at a weight ratio of about 1:1 to prepare a quantum dot complex. About 44 wt % of purified quantum dot complex, about 54 wt % of 1,6-hexanediol diacrylate (HDDA) and about 1 wt % of 2,4,6-trimethylbenzoyl-diphenyl phosphine oxide were mixed to prepare a quantum dot composition.

### 2) Quantum Dot Composition 2

A quantum dot composition was prepared by the same method as that of quantum dot composition 1 except for changing the weight ratio of the first sub quantum dot composition and the second sub quantum dot composition to about 2:1.

### 3) Quantum Dot Composition 3

A quantum dot composition was prepared by the same method as that of quantum dot composition 1 except for changing the weight ratio of the first sub quantum dot composition and the second sub quantum dot composition to about 3:1.

### 4) Quantum Dot Composition 4

A quantum dot composition was prepared by the same method as that of quantum dot composition 1 except for changing the weight ratio of the first sub quantum dot composition and the second sub quantum dot composition to about 1:2.

### 5) Quantum Dot Composition 5

A quantum dot composition was prepared by the same method as that of quantum dot composition 1 except for changing the weight ratio of the first sub quantum dot composition and the second sub quantum dot composition to about 1:3.

### 6) Comparative Quantum Dot Composition 1

A quantum dot composition was prepared by the same method as that of quantum dot composition 1 except for using a single type quantum dot of InP/ZnSeS instead of two types of quantum dots, and omitting a light irradiation step. Thus, comparative quantum dot composition 1 includes a single type quantum dot of InP/ZnSeS and has a structure in which TiO₂ and the InP/ZnSeS quantum dot are not connected via a ligand chemical bond.

### 7) Comparative Quantum Dot Composition 2

A quantum dot composition was prepared by the same method as that of quantum dot composition 1 except for using a single type quantum dot of InP/ZnSeS instead of two types of quantum dots. Thus, comparative quantum dot composition 2 includes a single type quantum dot of InP/ZnSeS and has a structure in which TiO₂ and the InP/ZnSeS quantum dot are connected via a ligand chemical bond.

### 8) Comparative Quantum Dot Composition 3

A quantum dot composition was prepared by the same method as that of quantum dot composition 1 except for using a single type quantum dot of AgInGaS/GaS instead of two types of quantum dots, and omitting a light irradiation step. Thus, comparative quantum dot composition 3 includes a single type quantum dot of AgInGaS/GaS and has a structure in which TiO₂ and the AgInGaS/GaS quantum dot are not connected via a ligand chemical bond.

### 9) Comparative Quantum Dot Composition 4

A quantum dot composition was prepared by the same method as that of quantum dot composition 1 except for using a single type quantum dot of AgInGaS/GaS instead of two types of quantum dots. Thus, comparative quantum dot composition 4 includes a single type quantum dot of AgInGaS/GaS and has a structure in which TiO₂ and the AgInGaS/GaS quantum dot are connected via a ligand chemical bond.

### 10) Comparative Quantum Dot Composition 5

A quantum dot composition was prepared by the same method as that of quantum dot composition 1 except for omitting a light irradiation step. Thus, comparative quantum dot composition 5 corresponds to a case of having a structure in which TiO₂, and the InP/ZnSeS and AgInGaS/GaS quantum dots are not connected via a ligand chemical bond compared to quantum dot composition 1.

### 11) Comparative Quantum Dot Composition 6

A quantum dot composition was prepared by the same method as that of quantum dot composition 2 except for omitting a light irradiation step. Thus, comparative quantum dot composition 6 corresponds to a case of having a structure in which TiO₂, and the InP/ZnSeS and AgInGaS/GaS quantum dots are not connected via a ligand chemical bond compared to quantum dot composition 2.

### 12) Comparative Quantum Dot Composition 7

A quantum dot composition was prepared by the same method as that of quantum dot composition 3 except for omitting a light irradiation step. Thus, comparative quantum dot composition 7 corresponds to a case of having a structure in which TiO₂, and the InP/ZnSeS and AgInGaS/GaS quantum dots are not connected via a ligand chemical bond compared to quantum dot composition 3.

### 13) Comparative Quantum Dot Composition 8

A quantum dot composition was prepared by the same method as that of quantum dot composition 4 except for omitting a light irradiation step. Thus, comparative quantum dot composition 8 corresponds to a case of having a structure in which TiO₂, and the InP/ZnSeS and AgInGaS/GaS quantum dots are not connected via a ligand chemical bond compared to quantum dot composition 4.

### 14) Comparative Quantum Dot Composition 9

A quantum dot composition was prepared by the same method as that of quantum dot composition 5 except for omitting a light irradiation step. Thus, comparative quantum dot composition 9 corresponds to a case of having a structure in which TiO₂, and the InP/ZnSeS and AgInGaS/GaS quantum dots are not connected via a ligand chemical bond compared to quantum dot composition 5.

### 2. Formation and Evaluation of Light Conversion Pattern

Light conversion patterns of Examples 1 to 5 and Comparative Examples 1 to 9 were formed using the quantum dot compositions prepared using quantum dot compositions 1 to 5 and comparative quantum dot compositions 1 to 9. The quantum dot compositions prepared were discharged on a glass substrate by an inkjet method to form films, exposed and cured to form light conversion patterns with a thickness of about 10 μm.

In Table 1, the external quantum efficiency (EQE) and absorption ratio according to the Examples and the Comparative Examples were measured and shown. The external quantum efficiency and absorption ratio were measured using a quantum efficiency measurement apparatus (QE2100, Otsuka Co.). In Table 1, with respect to the light conversion patterns, excited light of about 450 nm was irradiated, and the external quantum efficiency was measured and shown. The external quantum efficiency can be calculated according to Equation 1 below. The absorption ratio is a blue light absorption ratio and represents the amount of residual light that does not return to the light source but remains in the light conversion pattern as compared to the amount of light irradiated to the light conversion pattern.

$$External quantum efficiency = {N}_{1} / {N}_{2} \times 100 \qquad [ Equation 1 ]$$

In Equation 1, N₁ represents the number of photons emitted from the quantum dot complex, and N₂ represents the number of photons of excited light provided to the quantum dot complex.

TABLE 1

| | | | Weight ratio | | | |
|---|---|---|---|---|---|---|
| | | | (first quantum dot | | | External |
| | | | complex:second | | | quantum |
| | First | Second | quantum dot | | Absorption | efficiency |
| Division | quantum dot | quantum dot | complex) | Scatterer | ratio (%) | (%) |
| Example 1 | InP/ZnSeS | AgInGaS/GaS | 1:1 | TiO₂ | 92 | 38 |
| Example 2 | InP/ZnSeS | AgInGaS/GaS | 2:1 | TiO₂ | 90 | 35 |
| Example 3 | InP/ZnSeS | AgInGaS/GaS | 3:1 | TiO₂ | 88 | 34 |
| Example 4 | InP/ZnSeS | AgInGaS/GaS | 1:2 | TiO₂ | 92 | 33 |
| Example 5 | InP/ZnSeS | AgInGaS/GaS | 1:3 | TiO₂ | 93 | 30 |
| Comparative | InP/ZnSeS | — | — | — | 84 | 34 |
| Example 1 | | | | | | |
| Comparative | InP/ZnSeS | — | — | TiO₂ | 86 | 34 |
| Example 2 | | | | | | |
| Comparative | — | AgInGaS/GaS | — | — | 92 | 25 |
| Example 3 | | | | | | |
| Comparative | — | AgInGaS/GaS | — | TiO₂ | 93 | 25 |
| Example 4 | | | | | | |
| Comparative | InP/ZnSeS | AgInGaS/GaS | 1:1 | — | 82 | 30 |
| Example 5 | | | | | | |
| Comparative | InP/ZnSeS | AgInGaS/GaS | 2:1 | — | 81 | 32 |
| Example 6 | | | | | | |
| Comparative | InP/ZnSeS | AgInGaS/GaS | 3:1 | — | 82 | 31 |
| Example 7 | | | | | | |
| Comparative | InP/ZnSeS | AgInGaS/GaS | 1:2 | — | 86 | 28 |
| Example 8 | | | | | | |
| Comparative | InP/ZnSeS | AgInGaS/GaS | 1:3 | — | 88 | 28 |
| Example 9 | | | | | | |

Referring to the results of Table 1, when comparing Examples 1 to 5 with Comparative Examples 1 and 2, it can be confirmed that the external quantum efficiency of Examples 1 to 5, including two different types of quantum dots of InP/ZnSeS and AgInGaS/GaS was similar to that of Comparative Examples 1 and 2, including a single type quantum dots of InP/ZnSeS, but the absorption ratio was higher in Examples 1 to 5. When comparing Examples 1 to 5 with Comparative Examples 3 and 4, it can be confirmed that the absorption ratio of Examples 1 to 5, including two different types of quantum dots of InP/ZnSeS and AgInGaS/GaS was similar to that of Comparative Examples 3 and 4, including a single type quantum dots of AgInGaS/GaS, but the external quantum efficiency was higher in Examples 1 to 5.

Referring to FIG. 7 and Table 1 together, in the case of the light conversion pattern including two different types of quantum dots of InP/ZnSeS and AgInGaS/GaS, it can be confirmed that the overlap between an absorption wavelength spectrum and emission wavelength spectrum was small and the external quantum efficiency was increased compared to the light conversion pattern including a single type of quantum dots of each of InP/ZnSeS and AgInGaS/GaS. If the overlap between the absorption wavelength spectrum and emission wavelength spectrum increases, the re-excitation and re-absorption of quantum dots increase and defects of deteriorating the emission efficiency of the quantum dots may occur. However, if a light conversion pattern is formed using two different types of quantum dots, the overlap between the absorption wavelength spectrum and emission wavelength spectrum may be controlled small, and accordingly, the decrease of efficiency due to the re-excitation and re-absorption of quantum dots may be prevented.

When comparing Example 1 with Comparative Example 5, Example 2 with Comparative Example 6, Example 3 with Comparative Example 7, Example 4 with Comparative Example 8, and Example 5 with Comparative Example 8, including two types of different quantum dots, it can be confirmed that Examples 1 to 5 showed higher blue light absorption ratio and higher external quantum efficiency compared to Comparative Examples 5 to 9, respectively.

When comparing Examples 1 to 5, it can be confirmed that Examples 1 and 2, in which the weight ratio of the first sub quantum dot complex and the second sub quantum dot complex is about 1:1 to about 2:1, showed higher external quantum efficiency by about 35% or more and about 90% or more blue light absorption ratio compared to other Examples. In conclusion, it can be found that the optical properties of the light conversion pattern can be controlled by controlling the weight ratio of two different types of the quantum dots. As shown in Table 1, when a weight ratio of the first sub quantum dot complex to the second quantum dot complex is controlled to within a range of about 1:1 to about 2:1, high light efficiency increasing effect can be predicted.

The light conversion patterns of the Examples include two types of quantum dots including different core materials emitting the same color of light, and external quantum efficiency and blue light absorption ratio can be increased compared to the light conversion pattern including a single type of quantum dots. Since the light conversion patterns of the Examples include a scatterer and two types of quantum dots connected from each other by a ligand, the dispersibility of two different types of quantum dots may be improved, and the degradation of light absorption due to particle aggregation may be prevented. Since the scatterer is connected with two types of quantum dots, light not absorbed by the quantum dots can be scattered by the scatterer and readily absorbed by adjacent quantum dots. Accordingly, the light conversion pattern of an embodiment may show high emission efficiency.

According to an embodiment, a quantum dot composition capable of exhibiting high quantum efficiency may be provided.

According to an embodiment, a display device showing improved luminous efficiency properties by including quantum dots showing high quantum efficiency may be provided.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A quantum dot composition comprising:
a scatterer;
a first quantum dot comprising a first core;
a second quantum dot comprising a second core that is different from the first core;
a first ligand bonded to a surface of the first quantum dot;
a second ligand bonded to a surface of the second quantum dot; and
a scatterer ligand bonded to a surface of the scatterer, wherein
the first ligand and the second ligand each makes a chemical bond to the scatterer ligand.

2. The quantum dot composition of claim 1, wherein the first quantum dot and the second quantum dot each absorbs first light to emit second light that has a wavelength that is longer than a wavelength of the first light.

3. The quantum dot composition of claim 1, wherein a maximum emission wavelength range of the first quantum dot and a maximum emission wavelength range of the second quantum dot are each independently in a range of about 510 nm to about 550 nm.

4. The quantum dot composition of claim 1, wherein
the first core comprises a first semiconductor nanocrystal,
the second core comprises a second semiconductor nanocrystal, and
the first semiconductor nanocrystal and the second semiconductor nanocrystal are each independently a Group II-VI compound, a Group III-VI compound, a Group I-III-VI compound, a Group III-V compound, a Group III-II-V compound, a Group IV-VI compound, a Group IV element, a Group IV compound, or a combination thereof.

5. The quantum dot composition of claim 1, wherein
the first core comprises InP, and
the second core comprises AgInGaS.

6. The quantum dot composition of claim 1, wherein
the first ligand comprises:
a first head part that is bonded to the surface of the first quantum dot; and
a first tail part that is separated from the surface of the first quantum dot and makes a chemical bond to the scatterer ligand, and
the second ligand comprises:
a second head part that is bonded to the surface of the second quantum dot; and
a second tail part that is separated from the surface of the second quantum dot and makes a chemical bond to the scatterer ligand.

7. The quantum dot composition of claim 6, wherein
the first ligand further comprises a first connection part connecting the first head part and the first tail part, and
the second ligand further comprises a second connection part connecting the second head part and the second tail part.

8. The quantum dot composition of claim 1, wherein a sum of the amount of the first quantum dot and the amount of the second quantum dot is in a range of about 30 wt % to about 38 wt %, based on a total weight of the quantum dot composition.

9. The quantum dot composition of claim 1, wherein an amount of the scatterer is in a range of about 2 wt % to about 8 wt %, based on a total weight of the quantum dot composition.

10. The quantum dot composition of claim 1, wherein the scatterer comprises:
a first scatterer in which a first scatterer ligand that makes a chemical bond to the first ligand is bonded to a surface of the first scatterer; and
a second scatterer in which a second scatterer ligand that makes a chemical bond to the second ligand is bonded to a surface of the second scatterer.

11. The quantum dot composition of claim 10, wherein
a sum of the amounts of the first quantum dots, the first ligand, the first scatterer and the first scatterer ligand is defined as a first weight,
a sum of the amounts of the second quantum dots, the second ligand, the second scatterer and the second scatterer ligand is defined as a second weight, and
a ratio of the first weight to the second weight is in a range of about 1:1 to about 2:1.

12. The quantum dot composition of claim 1, wherein
the first quantum dot further comprises a first shell surrounding the first core,
the second quantum dot further comprises a second shell surrounding the second core,
the first ligand is bonded to a surface of the first shell, and
the second ligand is bonded to a surface of the second shell.

13. A display device comprising:
a display panel; and
a light conversion layer disposed on the display panel and comprising a plurality of light control parts, wherein
at least one of the plurality of the light control parts comprises a quantum dot complex,
the quantum dot complex comprises:
a scatterer;
a first quantum dot comprising a first core;
a second quantum dot comprising a second core that is different from the first core;
a first ligand bonded to a surface of the first quantum dot;
a second ligand bonded to a surface of the second quantum dot; and
a scatterer ligand bonded to a surface of the scatterer, and
the first ligand and the second ligand each makes a chemical bond to the scatterer ligand.

14. The display device of claim 13, wherein
the display panel comprises a light emitting element producing first light, and
the light conversion layer comprises:
a first light control part that transmits the first light;
a second light control part that converts the first light into second light; and
a third light control part that converts the first light into third light.

15. The display device of claim 13, wherein a blue light absorption rate of the light control part comprising the quantum dot complex among the plurality of the light control parts is greater than or equal to about 90%.

16. The display device of claim 13, wherein when excited light having a wavelength of about 450 nm is irradiated to the light control part comprising the quantum dot complex among the plurality of the light control parts, an external quantum efficiency (EQE) is greater than or equal to about 35%.

17. A method for manufacturing a quantum dot composition, the method comprising:
providing a first quantum dot with a first ligand bonded to a surface of the first quantum dot, the first quantum dot comprising a first core;
providing a second quantum dot with a second ligand bonded to a surface of the second quantum dot, the second quantum dot comprising a second core that is different from the first core;
providing a scatterer with a scatterer ligand bonded to a surface of the scatterer;
mixing the first quantum dot with the first ligand bonded thereto, the second quantum dot with the second ligand bonded thereto, and the scatterer with the scatterer ligand bonded thereto to provide a preliminary quantum dot composition; and
providing the preliminary quantum dot composition with heat or light to make a chemical bond between the first ligand and the scatterer ligand and between the second ligand and the scatterer ligand.

18. The method for manufacturing a quantum dot composition of claim 17, wherein
the scatterer ligand comprises a first functional group that makes a chemical bond to each of the first ligand and the second ligand, and
the first functional group comprises at least one of a thiol group, an amine group, a hydroxyl group, an azide group, and an oxetanyl group.

19. The method for manufacturing a quantum dot composition of claim 17, wherein
the first ligand comprises a second functional group that makes a chemical bond to the first functional group,
the second ligand comprises a third functional group that makes a chemical bond to the first functional group, and
the second functional group and the third functional group each independently comprises at least one of an alkenyl group, an alkynyl group, a carboxyl group, an acyl halide, and a (meth)acrylate group.

20. The method for manufacturing a quantum dot composition of claim 17, wherein
the providing of the preliminary quantum dot composition comprises:
mixing the first quantum dot with the first ligand bonded thereto and the scatterer with the scatterer ligand bonded thereto to provide a first preliminary quantum dot composition; and
mixing the second quantum dot with the second ligand bonded thereto and the scatterer with the scatterer ligand bonded thereto to provide a second preliminary quantum dot composition; and
the providing the preliminary quantum dot composition with heat or light to make a chemical bond between the first ligand and the scatterer ligand and between the second ligand and the scatterer ligand comprises:
providing each of the first preliminary quantum dot composition and the second preliminary quantum dot composition with heat or light; and
mixing the first preliminary quantum dot composition that has been provided with the heat or light and the second preliminary quantum dot composition that has been provided with the heat or light.
